(19) United States
(12) Patent Application Publication
(10) Pub. No.: US 2026/0247872 A1
(43) Pub. Date: Aug. 20, 2026

(54) CONFIGURABLE QUBIT CIRCUITS, SUPERCONDUCTING PROCESSORS INCLUDING CONFIGURABLE QUBIT CIRCUITS, AND METHODS OF CONFIGURING THEREOF

(71) Applicant: 1372934 B.C. LTD., Burnaby (CA)

(72) Inventors: Mohammad H. Amin, Coquitlam (CA); Emile M. Hoskinson, Vancouver (CA); Min Jan Tsai, Richmond (CA)

(21) Appl. No.: 19/162,158

(22) PCT Filed: Mar. 28, 2024
(86) PCT No.: PCT/US2024/021882

§ 371 Date: Sep. 4, 2025

Related U.S. Application Data
(60) Provisional application No. 63/455,091, filed on Mar. 28, 2023.

(51) Int. Cl. H10N 60/82; G06N 10/40; H10N 60/12; H10N 60/80; H10N 69/00

(52) U.S. Cl. CPC H10N 60/82; G06N 10/40; H10N 60/12; H10N 60/805; H10N 69/00

(57) ABSTRACT

Superconducting circuits providing a configurable qubit architecture may include: superconductive arms having an open shape terminating at two connection nodes; a set of Josephson junctions, each electrically arranged between connection nodes of one superconductive arm; a set of arm connection lines extending between connection nodes of each superconductive arm and connection nodes of other superconductive arms; and, a set of tunable connectors that interrupt arm connection lines. Tunable connectors can be selectively programmed to “ON” or “OFF” states, enabling or inhibiting current flow across arm connection lines, and electrically coupling or un-coupling superconductive arms to define closed superconductive paths of qubits. The superconducting circuits are configurable to provide a qubit arrangement suited to solving a problem on a quantum processor, such that embedding the problem topological representation uses fewer chains to represent relationships between problem variables. Methods of programming the superconducting circuits and performing coupling compensation are provided.

### CROSS-REFERENCE TO RELATED APPLICATION

This patent application claims priority of U.S. Patent Application No. 63/455,091, filed on Mar. 28, 2023, the entire disclosure of which is hereby incorporated by reference herein for all purposes.

### FIELD

This disclosure generally relates to qubits in superconducting processor architecture, and, more particularly, configurable qubit circuits in superconducting processor architecture.

### BACKGROUND

### Quantum Devices

Quantum devices are structures in which quantum mechanical effects are observable. Quantum devices include circuits in which current transport is dominated by quantum mechanical effects. Such devices include spintronics, and superconducting circuits. Both spin and superconductivity are quantum mechanical phenomena. Quantum devices can be used for measurement instruments, in computing machinery, and the like.

### Quantum Processor

A quantum processor may take the form of a superconducting quantum processor. A superconducting quantum processor may include a number of superconducting qubits and associated local bias devices. A superconducting quantum processor may also include couplers that selectively provide communicative coupling between qubits.

In one implementation, the superconducting qubit includes a superconducting loop interrupted by a Josephson junction. The ratio of the inductance of the Josephson junction to the geometric inductance of the superconducting loop can be expressed as 2πLI_{c}/Φ₀ (where L is the geometric inductance, Ic is the critical current of the Josephson junction, and Φ₀ is the flux quantum). The inductance and the critical current can be selected, adjusted, or tuned, to increase the ratio of the inductance of the Josephson junction to the geometric inductance of the superconducting loop, and to cause the qubit to be operable as a bistable device. In some implementations, the ratio of the inductance of the Josephson junction to the geometric inductance of the superconducting loop of a qubit is approximately equal to three.

In one implementation, the superconducting coupler includes a superconducting loop interrupted by a Josephson junction. The inductance and the critical current can be selected, adjusted, or tuned, to decrease the ratio of the inductance of the Josephson junction to the geometric inductance of the superconducting loop, and to cause the coupler to be operable as a monostable device. In some implementations, the ratio of the inductance of the Josephson junction to the geometric inductance of the superconducting loop of a coupler is approximately equal to, or less than, one.

Further details and embodiments of example quantum processors that may be used in conjunction with the present systems and devices are described in, for example, U.S. Pat. Nos. 7,533,068; 8,008,942; 8, 195,596; 8, 190,548; and 8,421,053.

### Superconducting Qubits

Superconducting qubits are solid state qubits based on circuits of superconducting materials. Operation of superconducting qubits is based on the underlying principles of magnetic flux quantization, and Josephson tunneling. Superconducting effects can be present in different configurations, and can give rise to different types of superconducting qubits including flux, phase, charge, and hybrid qubits. The different configurations can vary in the topology of the loops, the placement of the Josephson junctions, and the physical parameters of elements of the superconducting circuits, such as inductance, capacitance, and Josephson junction critical current.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

Quantum processors known in the art have a fixed circuit architecture, and subsequently a fixed qubit arrangement. In quantum annealing and/or adiabatic quantum computing, a topological representation of a problem is embedded onto the circuit architecture of the quantum processor, such that qubits, couplers, and chains thereof represent problem variables and their relationships to one another. Different circuit architectures may be best suited for different problems, and use of a quantum processor having a non-optimal qubit arrangement may result in embeddings with disadvantageously long or many chains, limiting problem complexity and solution accuracy. A quantum processor having a dynamically configurable circuit architecture can allow for the qubit arrangement to be repeatedly reconfigured after manufacture to best suit each problem to be solved.

In one aspect, there is provided a superconducting circuit having a configurable architecture of one or more superconducting qubits. The superconducting circuit includes: a set of superconductive arms, each of the superconductive arms of the set of superconductive arms respectively including a first connection node, a second connection node, and a trace of superconductive material having an open shape that extends from the first connection node to the second connection node; a set of Josephson junctions, each Josephson junction of the set of Josephson junctions being electrically arranged between the first and the second connection nodes of a respective one of the superconductive arms to selectively close the open shape; and, a configuration circuit. The configuration circuit includes a set of superconductive arm connection lines and a set of tunable connectors. Each first connection node of each superconductive arm is physically and electrically connected to at least one of the first or the second connection node of at least one other superconductive arm via one or more superconductive arm connection lines extending therebetween, and each second connection node of each superconductive arm is physically and electrically connected to at least one of the first or the second connection node of at least one other superconductive arm via one or more superconductive arm connection lines extending therebetween. Each tunable connector of the set of tunable connectors interrupts a respective superconductive arm connection line of the set of superconductive arm connection lines, and the tunable connectors selectively operable (e.g., switchable) to control a flow of current therethrough and across two or more superconductive arm connection lines between at least two superconductive arms and configure closed superconductive paths that form the one or more superconducting qubits.

In some implementations, each Josephson junction of the set of Josephson junctions is operable to tune a double-well potential of a superconducting qubit of the one or more superconducting qubits, and each superconducting qubit includes: one Josephson junction of the set of Josephson junctions or two Josephson junctions of the set of Josephson junctions.

In some implementations, each Josephson junction of the set of Josephson junctions is one of: a compound Josephson junction (CJJ) or a compound-compound Josephson junction (CCJJ).

In some implementations, the superconducting circuit is configurable such that the one or more superconducting qubits selectively includes at least one qubit with a respective closed superconductive path formed of more than one superconducting qubit loops. Each superconducting qubit loop includes: at least two superconductive arms of the set of superconductive arms; at least two superconductive arm connection lines interrupted by tunable connectors of the set of tunable connectors tuned to enable current flow between the at least two superconductive arms, each of the at least two superconductive arm connection lines electrically arranged to connect first and second connection nodes of each of the at least two superconductive arms to one of a first connection node or a second connection node of each other one of the at least two superconductive arms; and, one or more Josephson junctions of the set of Josephson junctions, each Josephson junction of the one or more Josephson junctions being electrically arranged between respective first and second connection nodes of a respective one of the at least two superconductive arms.

In some implementations, one or more tunable connectors of the set of tunable connectors tuned to enable current flow between the at least two superconductive arms are operable as one or more L-tuners to tune a qubit inductance of the at least one qubit having more than one superconducting qubit loop.

In some implementations, the one or more superconducting qubits include one or more single-loop qubits. Each single-loop qubit includes: a respective superconductive arm of the set of superconductive arms, and at least a portion of a respective Josephson junction of the set of Josephson junctions electrically arranged between a respective first and second connection node of the respective superconductive arm. Each of the superconductive arm connection lines directly coupled to the first and the second connection nodes of the respective superconductive arm are interrupted by tunable connectors of the set of tunable connectors configured to the “OFF” state.

In some implementations, the superconducting circuit is configured to include a first superconducting qubit and a second superconducting qubit, and at least one tunable connector of the set of tunable connectors set to the “OFF” state provides an undesired first coupling between the first and the second qubit in a first direction. The superconducting circuit further includes at least one coupling superconducting loop to fixedly and persistently magnetically couple the first superconducting qubit and the second superconducting qubit with a second coupling in a second direction that opposes the first direction. The second coupling counteracts the first coupling.

In some implementations, the at least one tunable connector of the set of tunable connectors in the “OFF” state is tunable to modify a magnitude of the first coupling to match a magnitude of the second coupling.

In some implementations, each trace of superconducting material of the set of superconductive arms, the set of Josephson junctions, and the set of tunable connectors each comprise of one or more materials that exhibit superconducting behavior at and below a respective critical temperature of each of the one or more materials.

In some implementations, each tunable connector of the set of tunable connectors is selectively configurable to transmit current therethrough via modification of a respective tunable connector inductance, and each respective tunable connector inductance is modifiable through a bias signal transmitted to each tunable connector via a respective bias interface.

In some implementations, a maximum number of the one or more superconducting qubits corresponds to a number of Josephson junctions in the set of Josephson junctions.

In some implementations, the configurable architecture of one or more superconducting qubits includes one of: at least one qubit with a respective closed superconductive path having more than one superconducting qubit loop; at least one qubit with a respective closed superconductive path having one superconducting qubit loop; or, a combination thereof.

In some implementations, wherein the configurable architecture of one or more superconducting qubits of the superconducting circuit is reconfigurable to provide a different architecture of one or more superconducting qubits based on selective reconfiguration of the set of tunable connectors to electrically couple superconductive arms of the set of superconductive arms.

In some implementations, a respective trace of at least one of the superconductive arms of the set of superconductive arms is U-shaped.

In an aspect, there is provided a method to configure one or more superconducting qubits on a superconducting circuit. The superconducting circuit includes: a set of superconductive arms, each comprised of a trace of superconductive material having an open shape that extends between a respective first and second connection node; a set of Josephson junctions, each electrically arranged between the first and the second connection node of a respective one of the superconductive arms; a set of superconductive arm connection lines extending between one of the first and the second connection node of a superconductive arm of the set of superconductive arms and one of the first and the second connection node of another superconductive arm of the set of superconductive arms; and, a set of tunable connectors, each interrupting a respective superconductive arm connection line. The method includes: transmitting a plurality of bias signals to the superconducting circuit, each bias signal of the plurality of bias signals transmitted to a respective tunable connector of the set of tunable connectors; and based on the plurality of bias signals, configuring a first subset of tunable connectors of the set of tunable connectors to permit current transmission therethrough. An arrangement of superconductive arm connection lines that are interrupted by the first subset of tunable connectors selectively electrically couples superconductive arms of the set of superconductive arms to configure a closed superconductive path of each qubit of the one or more superconducting qubits. Each closed superconductive path comprising at least: at least one superconductive arm of the set of superconductive arms, and at least a portion of at least one Josephson junction of the set of Josephson junctions.

In some implementations, prior to the transmitting the plurality of bias signals to the superconducting circuit, the method includes: inputting a desired qubit configuration to a digital computer; and using the digital computer, instructing an analog computer that includes the superconducting circuit to perform configuration of the one or more superconducting qubits by transmitting one or more control signals.

In some implementations, the method includes: receiving, by one or more digital-to-analog converters (DACs) of the analog computer, the one or more control signals transmitted by the digital computer; and generating, by the one or more DACs, the plurality of bias signals. The transmitting the plurality of bias signals to the superconducting circuit includes applying each bias signal to the respective tunable connector via a respective bias interface.

In some implementations, the applying each bias signal to a respective tunable connector via a respective bias interface includes one of: applying each bias signal to a respective tunable connector via an analog line, or coupling each bias signal to a respective tunable connector via an inductive interface.

In some implementations, the configuring the first subset of tunable connectors of the tunable connectors to permit current transmission through the first subset of tunable connectors includes: applying a first subset of the plurality of bias signals to configure the first subset of tunable connectors to an “ON” state; and applying a second subset of the plurality of bias signals to configure a second subset of tunable connectors to an “OFF” state, wherein the second subset of tunable connectors configured to the “OFF” state inhibit current transmission through the second subset of tunable connectors.

In some implementations, the method further includes selectively tuning one or more tunable connectors of the first subset of tunable connectors to compensate for qubit inductance of a superconducting qubit formed by a respective closed superconductive path that includes a superconductive arm connection line interrupted by the one or more tunable connectors.

In some implementations, the superconducting circuit is included as part of an analog computer that is communicatively coupled to a digital computer. The selectively tuning the one or more tunable connectors of the first subset of tunable connectors includes: receiving, by one or more digital-to-analog converters (DACs) of the analog computer, one or more inductance tuning control signals transmitted by the digital computer; generating, by the one or more DACs, one or more inductance tuning bias signals; and transmitting each of the one or more inductance tuning bias signals to a respective one of the one or more tunable connectors of the first subset of tunable connectors.

In some implementations, the method further includes performing coupling compensation between a first and a second superconducting qubit configured on the superconducting circuit having a first coupling therebetween having a first direction. The performing coupling compensation includes: fixedly and persistently magnetically coupling the first superconducting qubit to the second superconducting qubit by a second coupling having a second direction that substantially opposes the first direction; and tuning the first coupling through at least one tunable connector of a second subset of tunable connectors of the set of tunable connectors to counteract the second coupling, including matching a magnitude of the first coupling to a magnitude of the second coupling.

In some implementations, the superconducting circuit is included as part of an analog computer that is communicatively coupled to a digital computer. The tuning the first coupling through at least one tunable connector of the second subset of tunable connectors to counteract the second coupling includes: receiving, by one or more digital-to-analog converters (DACs) of the analog computer, a coupling compensation control signal transmitted by the digital computer; generating, by the one or more DACs, one or more coupling compensation bias signals; and transmitting each of the one or more coupling compensation signals to a respective one of the at least one tunable connectors of the second subset of tunable connectors via a respective tunable connector interface.

In some implementations, the fixedly and persistently magnetically coupling the first and second superconducting qubits includes providing at least one coupling superconducting loop, each coupling superconducting loop to magnetically couple a superconducting loop of the first superconducting qubit to a superconducting loop of the second superconducting qubit.

In an aspect, there is provided a method to configure one or more superconducting qubits on a superconducting circuit. The method is performed by a digital processor in communication with an analog computer that comprises the superconducting circuit. The superconducting circuit includes: a set of superconductive arms, each comprised of a trace of superconductive material having an open shape that extends between a respective first and second connection node; a set of Josephson junctions, each electrically arranged between the first and the second connection node of a respective one of the superconductive arms; a set of superconductive arm connection lines extending between one of the first and the second connection node of a superconductive arm of the set of superconductive arms and one of the first and the second connection node of another superconductive arm of the set of superconductive arms; and, a set of tunable connectors, each interrupting a respective superconductive arm connection line. The method includes: receiving a qubit configuration specification; and instructing the analog computer to configure the superconducting circuit according to the received qubit configuration specification through transmission of a plurality of control signals. The plurality of control signals are to tune a first subset of tunable connectors to permit current transmission therethrough to selectively electrically couple superconductive arms of the set of superconductive arms and establish a closed superconductive path of each qubit of the one or more superconducting qubits. Each closed superconductive path includes at least: at least one superconductive arm of the set of superconductive arms, and at least a portion of at least one Josephson junction of the set of Josephson junctions.

In some implementations, the instructing the analog computer to configure the superconducting circuit according to the received qubit configuration specification through transmission of a plurality of control signals includes: transmitting the plurality of control signals to one or more digital-to-analog converters (DACs) of the analog computer to generate a plurality of bias signals for application to the set of tunable connectors via bias interfaces. The application of the plurality of bias signals tunes the first subset of tunable connectors to permit current transmission therethrough.

In some implementations, the instructing the analog computer to configure the superconducting circuit according to the received qubit configuration specification through transmission of a plurality of control signals includes: transmitting a first subset of control signals of the plurality of control signals to configure the first subset of tunable connectors to an “ON” state; and transmitting a second subset of the plurality of control signals to configure a second subset of tunable connectors to an “OFF” state. The second subset of tunable connectors configured to the “OFF” state inhibit current transmission through the second subset of tunable connectors.

In some implementations, the method further includes: instructing the analog computer to selectively tune one or more tunable connectors of the first subset of tunable connectors to compensate for qubit inductance of a superconducting qubit formed by a respective closed superconductive path that includes a superconductive arm connection line interrupted by the one or more tunable connectors.

In some implementations, the instructing the analog computer to selectively tune one or more tunable connectors of the first subset of tunable connectors to compensate for qubit inductance includes: transmitting one or more inductance tuning control signals to one or more digital-to-analog converters (DACs) of the analog computer to generate one or more inductance tuning bias signals for application to the one or more tunable connectors of the first subset of tunable connectors to tune inductance values.

In some implementations, the method further includes: instructing the analog computer to perform coupling compensation between a first and a second superconducting qubit configured on the superconducting circuit. The first and the second superconducting qubit having an undesired first coupling therebetween having a first direction and a second coupling having a second direction that substantially opposes the first direction. The second coupling is a fixed, persistent magnetic coupling. The instructing the analog computer to perform coupling compensation between a first and a second superconducting qubit includes: instructing the analog computer to tune the undesired first coupling through at least one tunable connector of a second subset of tunable connectors of the set of tunable connectors to counteract the second coupling, including matching a magnitude of the first coupling to a magnitude of the second coupling.

In some implementations, the instructing the analog computer to tune the undesired first coupling through at least one tunable connector of a second subset of tunable connectors of the set of tunable connectors to counteract the second coupling includes: transmitting a coupling compensation control signal to one or more digital-to-analog converters (DACs) of the analog computer to generate one or more coupling compensation bias signals for application to the at least one tunable connector of the second subset of tunable connectors.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1 is a schematic diagram of a hybrid computing system including a digital computer coupled to an analog computer, in accordance with the present systems, devices, and methods.

FIG. 2 is a schematic diagram of a circuit of an example superconducting quantum processor, according to at least one implementation.

FIG. 3A is a schematic diagram of an example flux qubit that has more than one superconducting loop, in accordance with the present systems, devices, and methods.

FIG. 3B is a schematic of a circuit comprising two flux qubits having a fixed galvanic coupling, in accordance with the present systems, devices, and methods.

FIG. 3C is a schematic of a circuit comprising two flux qubits having a programmable galvanic coupling, in accordance with the present systems, devices, and methods.

FIG. 3D is a schematic of a circuit comprising two flux qubits having an alternative programmable galvanic coupling, in accordance with the present systems, devices, and methods.

FIG. 3E is a schematic of a circuit comprising two multi-loop flux qubits having a fixed galvanic coupling, in accordance with the present systems, devices, and methods.

FIG. 4 is a schematic diagram of a superconducting circuit to program one or more qubits, in accordance with the present systems, devices, and methods.

FIG. 5A is a schematic diagram of the superconducting circuit of FIG. 4 programmed to provide flux qubits in one configuration.

FIG. 5B is a schematic diagram of the superconducting circuit of FIG. 4 programmed to provide two qubits in a different configuration.

FIG. 6A is a schematic diagram of the superconducting circuit of FIG. 4 programmed to provide one qubit in one configuration.

FIG. 6B is a schematic diagram of the superconducting circuit of FIG. 4 programmed to provide one qubit in a different configuration.

FIG. 7A is a schematic diagram of an alternative superconducting circuit to FIG. 4, in accordance with the present systems, devices, and methods.

FIG. 7B is a schematic diagram of the superconducting circuit of FIG. 7A programmed to provide two qubits in one configuration.

FIG. 7C is a schematic diagram of the superconducting circuit of FIG. 7A programmed to provide two qubits in a different configuration from that illustrated in FIG. 7B.

FIG. 8A is a schematic diagram of another alternative superconducting circuit to FIG. 4, in accordance with the present systems, devices, and methods. FIG. 8B is a schematic diagram of the superconducting circuit of FIG. 8A, programmed to provide two qubits in one configuration.

FIG. 9A illustrates coupling of the two qubits as configured in the configuration illustrated in FIG. 5A.

FIG. 9B illustrates coupling of the two qubits as configured in the configuration illustrated in FIG. 5B.

FIG. 10 is a flow diagram showing a method to configure a superconducting circuit to configure one or more qubits, in accordance with the present systems, devices, and methods.

FIG. 11 is a flow diagram showing a method to configure a coupling between two qubits provided by a programmable superconducting circuit, in accordance with the present systems, devices, and methods.

### DETAILED DESCRIPTION

### Preamble

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

As used in this specification and the appended claims, the terms “trace of superconducting material” and “traces of superconducting material” refer to any path of material that is superconductive at a specified critical temperature or critical current, without regard to the shape of the path (e.g., straight, segmented, crenulated, curved, in two-or three dimensions) and without regard to how the path of superconductive materials is formed (e.g., deposited on a surface of a substrate, grown on a surface of a substrate, drawn as a wire, or otherwise formed).

As used in this specification and the appended claims, the term “open shape of superconducting material” refers to a trace of superconducting material that does not in and of itself provide a closed current conducting path, although such can form part of a closed conducting path in conjunction with one or more of circuit elements (e.g., superconductive arm connection line and/or connecting CJJs).

Herein, “galvanic” coupling can refer to electrical coupling in which the coupled structures and/or devices share a common length of metal, and “direct galvanic coupling” can refer to galvanic coupling for which there are no interleaving metal layers between the coupled structures and/or devices.

The headings and Abstract of the Disclosure provided herein are for convenience only and do not interpret the scope or meaning of the implementations.

### Example Computing System

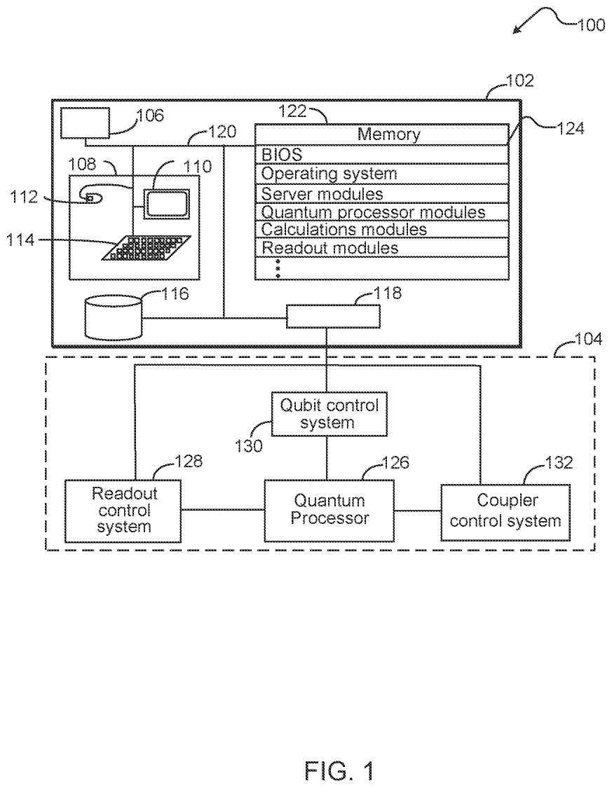

FIG. 1 illustrates a computing system 100 comprising a digital computer 102. The example digital computer 102 includes one or more digital processors 106 that may be used to perform classical digital processing tasks. Digital computer 102 may further include at least one system memory 122, and at least one system bus 120 that couples various system components, including system memory 122 to digital processor(s) 106. System memory 122 may store one or more sets of processor-executable instructions, which may be referred to as modules 124.

The digital processor(s) 106 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and/or combinations of the same.

In some implementations, computing system 100 comprises a quantum computer 104, which may include one or more quantum processors 126.

Quantum processor 126 may include at least one superconducting integrated circuit fabricated using systems and methods described in the present application. Digital computer 102 may communicate with quantum computer 104 via, for instance, a controller 118. Certain computations may be performed by quantum computer 104 at the instruction of digital computer 102, as described in greater detail herein.

Digital computer 102 may include a user input/output subsystem 108. In some implementations, the user input/output subsystem includes one or more user input/output components such as a display 110, mouse 112, and/or keyboard 114.

System bus 120 may employ any known bus structures or architectures, including a memory bus with a memory controller, a peripheral bus, and a local bus. System memory 122 may include non-volatile memory, such as read-only memory (“ROM”), static random-access memory (“SRAM”), Flash NAND; and volatile memory such as random-access memory (“RAM”) (not shown).

Digital computer 102 may also include other non-transitory computer-or processor-readable storage media or non-volatile memory 116. Non-volatile memory 116 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 116 may communicate with digital processor(s) via system bus 120 and may include appropriate interfaces or controllers 118 coupled to system bus 120. Non-volatile memory 116 may serve as long-term storage for processor-or computer-readable instructions, data structures, or other data (sometimes called program modules or modules 124) for digital computer 102.

Although digital computer 102 has been described as employing hard disks, optical disks and/or solid-state storage media, those skilled in the relevant art will appreciate that other types of non-transitory and non-volatile computer-readable media may be employed. Those skilled in the relevant art will appreciate that some computer architectures employ non-transitory volatile memory and non-transitory non-volatile memory. For example, data in volatile memory may be cached to non-volatile memory, or a solid-state disk that employs integrated circuits to provide non-volatile memory.

Various processor-readable or computer-readable and/or executable instructions, data structures, or other data may be stored in system memory 122. For example, system memory 122 may store instructions for communicating with remote clients and scheduling use of resources including resources on the digital computer 102 and quantum computer 104. Also, for example, system memory 122 may store at least one of processor executable instructions or data that, when executed by at least one processor, causes the at least one processor to execute the various algorithms to execute instructions. In some implementations system memory 122 may store processor-or computer-readable calculation instructions and/or data to perform pre-processing, co-processing, and post-processing to quantum computer 104. System memory 122 may store a set of quantum computer interface instructions to interact with quantum computer 104.

Quantum computer 104 may include at least one analog processor such as quantum processor 126. Quantum computer 104 may be provided in an isolated environment, for example, in an isolated environment that shields the internal elements of the quantum computer from heat, magnetic field, and other external noise. The isolated environment may include a refrigerator, for instance a dilution refrigerator, operable to cryogenically cool the analog processor, for example to temperature below approximately 1 K.

Quantum computer 104 may include programmable elements such as qubits, couplers, and other devices (also referred to herein as controllable devices). Qubits may be read out via readout control system 128. Readout results may be sent to other computer-or processor-readable instructions of digital computer 102. Qubits may be controlled via a qubit control system 130.

Qubit control system 130 may include on-chip Digital to Analog Converters (DACs) and analog lines that are operable to apply a bias to a target device.

Couplers that couple qubits may be controlled via a coupler control system 132. Couple control system 132 may include tuning elements such as on-chip DACs and analog lines.

### Example Superconducting Quantum Processor

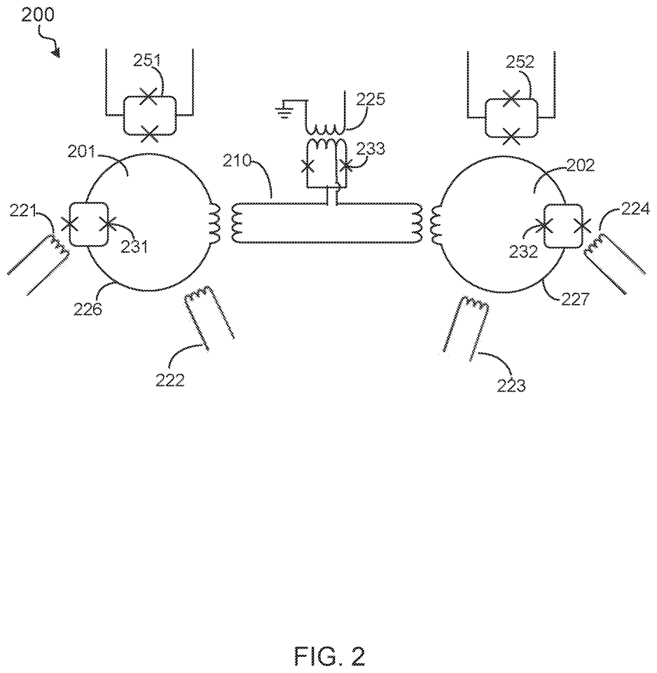

FIG. 2 illustrates a circuit 200 of an example superconducting quantum processor, according to at least one implementation. In some implementations, the superconducting quantum processor of circuit 200 may be quantum computer 104 shown in FIG. 1. Circuit 200 includes two superconducting qubits 201 and 202. Also shown is a tunable coupling (diagonal coupling) via coupler 210 between qubits 201 and 202 (i.e., providing 2-local interaction). While circuit 200 shown in FIG. 2 includes only two qubits 201, 202 and one coupler 210, those of skill in the art will appreciate that a superconducting quantum processor may include any number of qubits and any number of couplers coupling information between them.

Circuit 200 includes a plurality of interfaces 221, 222, 223, 224, 225 (221-225) that are used to configure and control the state of the superconducting quantum processor. Each of interfaces 221-225 can be realized by a respective inductive coupling structure, as illustrated, as part of a programming subsystem and/or an optional evolution subsystem. Alternatively, or in addition, interfaces 221-225 can be realized by a galvanic coupling structure. In some implementations, one or more of interfaces 221-225 may be driven by one or more flux storage devices or Digital-to-Analog Converters (DACs). Such a programming subsystem and/or optional evolution subsystem may be separate from the superconducting quantum processor, or may be included locally (i.e., on-chip with the superconducting quantum processor). For example, referring to computing system 100 of FIG. 1, locally included programming subsystem and/or optional evolution subsystem can be arranged as part of quantum computer 104.

In the operation of the superconducting quantum processor, interfaces 221 and 224 may each be used to couple a flux signal into a respective compound Josephson junction (CJJ) 231 and 232, respectively, of qubits 201 and 202.

Similarly, interfaces 222 and 223 may each be used to apply a flux signal into respective superconducting loops 226 and 227 of qubits 201 and 202.

Furthermore, interface 225 can be used to couple a flux signal into at least one CJJ 233 of coupler 210. Throughout this specification and the appended claims, the term “quantum processor” is used to generally describe a collection of physical qubits (e.g., qubits 201 and 202) and qubit couplers (e.g., coupler 210). The physical qubits 201 and 202 and the coupler 210 are referred to as the “controllable devices” of a quantum processor and their corresponding parameters are referred to as the “controllable parameters” of the quantum processor. In the context of a quantum processor, the term “programming subsystem” is used to generally describe the interfaces (e.g., “programming interfaces” 222, 223, and 225) used to apply the controllable parameters to the controllable devices of the superconducting quantum processor and other associated control circuitry and/or instructions. In some implementations, programming interfaces 222, 223, and 225 may include DACs. DACs may also be considered programmable devices that are used to control controllable devices such as qubits, couplers, and parameter tuning devices.

As previously described, the programming interfaces of the programming subsystem may communicate with other subsystems which may be separate from the quantum processor or may be included locally on the processor, such as arranged as part of quantum computer 104 of FIG. 1. The programming subsystem may be configured to receive programming instructions in a machine language of the quantum processor and execute the programming instructions to program the programmable and controllable devices in accordance with the programming instructions. In some implementations, where the quantum processor is implemented as quantum computer 104 of FIG. 1, the controllable devices may be arranged as part of quantum processor 126 and these other subsystems may be at least one of: readout control system 128, qubit control system 130, and coupler control system 132 of quantum computer 104. The initial programming instructions may be provided using digital computer 102 and sent to the quantum processor and its corresponding subsystems through controllers 118 (e.g., digital processor(s)).

Circuit 200 also includes readout devices 251 and 252, where readout device 251 is associated with qubit 201 and readout device 252 is associated with qubit 202. In the example implementation shown in FIG. 2, each of readout devices 251 and 252 includes a direct current superconducting quantum interference device (DC-SQUID) inductively coupled to the corresponding qubit. In the context of circuit 200, the term “readout subsystem” is used to generally describe the readout devices 251, 252 used to read out the final states of the qubits (e.g., qubits 201 and 202) in the superconducting quantum processor to produce a bit string. The readout subsystem may also include other elements, such as routing circuitry (e.g., latching elements, a shift register, or a multiplexer circuit) and/or may be arranged in alternative configurations (e.g., an XY-addressable array, an XYZ-addressable array, etc.), any of which may comprise DACs. Qubit readout may also be performed using alternative circuits, such as that described in U.S. Pat. No. 8,854,074. The behavior of the readout subsystem may be informed by signals transmitted from readout control system 128 in FIG. 1. Readout control system 128 may be coupled to readout devices 251 and 252 via DACs, analog lines, or other suitable means, While FIG. 2 illustrates only two physical qubits 201, 202, one coupler 210, and two readout devices 251, 252, a quantum processor (e.g., processor comprising circuit 200) may employ any number of qubits, couplers, and/or readout devices, including a larger number (e.g., hundreds, thousands or more) of qubits, couplers and/or readout devices. The application of the teachings herein to processors with a different (e.g., larger) number of computational components should be readily apparent to those of ordinary skill in the art.

A superconducting quantum processor may include other types of qubits besides superconducting flux qubits. For example, a superconducting quantum processor may include superconducting charge qubits, transmon qubits, and the like. Approaches described in the present application can be applied generally to any of the above-noted types of qubits, as well as to similar qubits as are known in the art.

In some implementations, circuit 200 of the superconducting processor can optionally be all or a portion of a superconducting processor used for quantum annealing and/or adiabatic quantum computing. In such implementations, plurality of interfaces 221-225 couple respective flux signals into qubits 201, 202 to realize parameters of the system Hamiltonian. For instance, the coupling of interfaces 221, 224 to qubits 201, 202 may provide a tunable tunneling term (the Δᵢ term), and the coupling may provide the off-diagonal ox terms of the system Hamiltonian. The use of interfaces 222, 223 to apply a flux signal into superconducting loops 226, 227 of qubits 201, 202 may realize the σᵢ terms (dimensionless local fields for the qubits), and the coupling may provide the diagonal σ^{z} terms in the system Hamiltonian. Lastly, interface 225 may be used to couple a flux signal into coupler 210, thereby realizing the Jᵢⱼ term(s) (dimensionless local fields for the couplers), for which the coupling may provide the diagonal of

$${σ}_{i}^{z} {σ}_{j}^{z}$$

terms in the system Hamiltonian. Examples of Hamiltonians (and their terms) used in quantum computing are described in greater detail in, for example, U.S. Pat. No. 9,424,526. In such implementations, parameters of the system Hamiltonian may be considered “controllable parameters” of the quantum processor.

In implementations where circuit 200 is all or a portion of a superconducting processor used for quantum annealing and/or adiabatic quantum computing, the example superconducting quantum processor may have an evolution subsystem including the interfaces (e.g., “evolution interfaces” 221, 224) used to evolve devices such as the qubits of circuit 200 and other associated control circuitry and/or instructions. For example, the evolution subsystem may include annealing signal lines and their corresponding interfaces (221, 224) to the qubits (201, 202).

In other implementations, circuit 200 of the superconducting processor can optionally be all or a portion of a superconducting processor used for gate-model quantum computing.

In some implementations, it may be beneficial to provide a multi-loop flux qubit, which can increase connectivity between qubits and thus influence the type and complexity of problems that may be solved by a quantum processor.

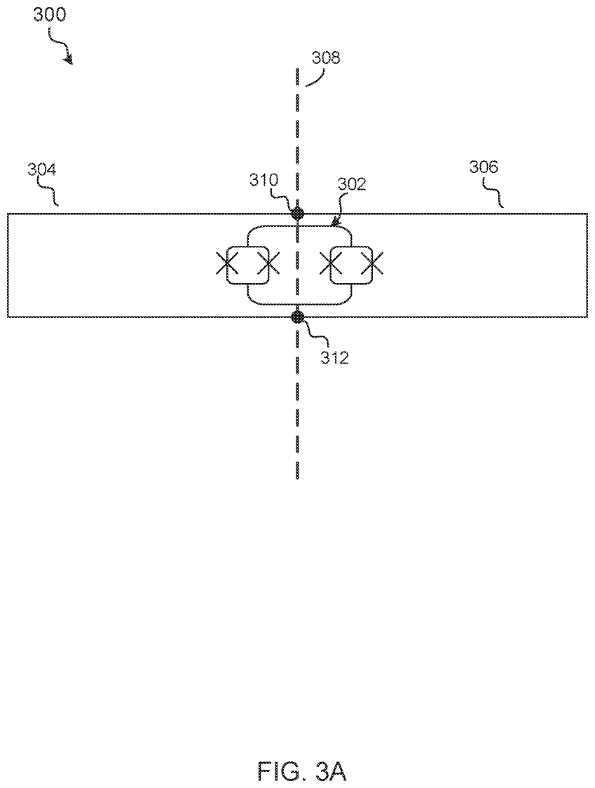

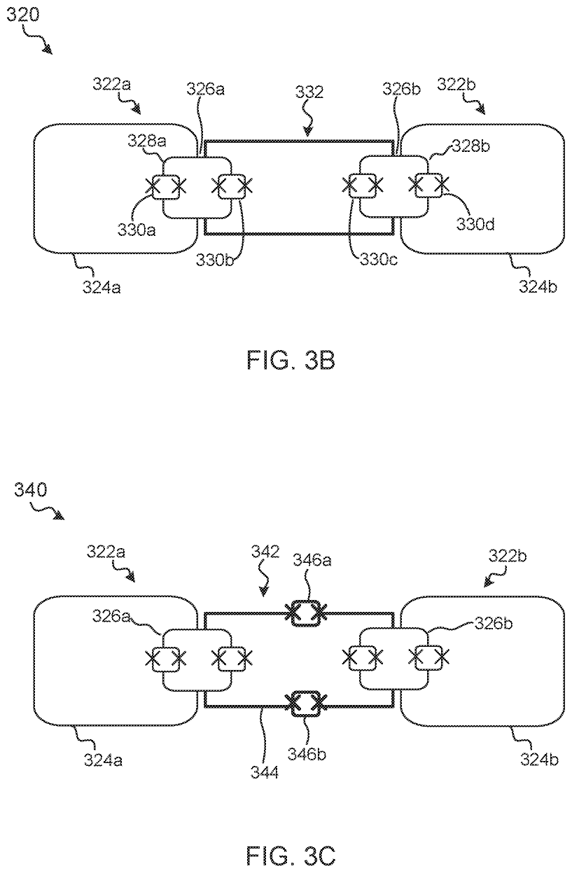

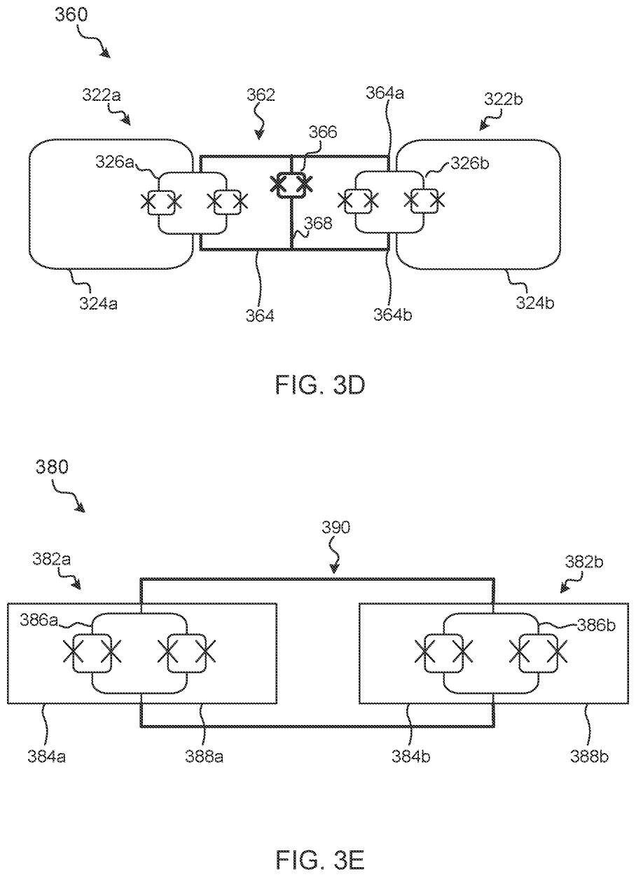

FIG. 3A illustrates an example flux qubit that has more than one superconducting loop, in accordance with the present systems, devices, and methods. A superconducting flux qubit 300 includes a loop of superconducting material interrupted by a Josephson junction 302, and the interrupted superconducting loop can be viewed as two superconducting loops.

In the illustrated implementation, Josephson junction 302 of superconducting flux qubit 300 is a compound-compound Josephson junction (CCJJ). However, this is not intended to be limiting and Josephson junction 302 may alternatively be a compound Josephson junction (CJJ).

Superconducting flux qubit 300 includes a first superconducting qubit loop 304 that provides a first superconducting path, and a second superconducting qubit loop 306 that provides a second superconducting path. Each of the first and the second superconducting path includes a portion of the loop of superconducting material and a portion of Josephson junction 302. First superconducting qubit loop 304 and second superconducting qubit loop 306 are electrically coupled in parallel across Josephson junction 302.

Although superconducting flux qubit 300 includes two superconducting qubit loops 304, 306, a superconducting flux qubit may be designed to include any number of superconducting qubit loops, as long as the superconducting qubit loops are coupled across at least one Josephson junction.

Superconducting flux qubit 300 is formed of material that exhibits superconducting behavior at and below a critical temperature T_{c}. At least a portion of each of first superconducting qubit loop 304, second superconducting qubit loop 306, and Josephson junction 302 may comprise a same or different superconducting material than the other components of superconducting flux qubit 300. Each superconducting material may have a respective critical temperature T_{c}. In some implementations, superconducting flux qubit 300 can comprise one or more of: aluminum, niobium, tantalum, and one or more other superconducting materials.

In the example implementation of FIG. 3A, first superconducting qubit loop 304 and second superconducting qubit loop 306 of superconducting flux qubit 300 are substantially symmetric about an axis 308 of Josephson junction 302 (e.g., an axis of symmetry). Axis 308 intersects a first node 310 at a first point where first superconducting qubit loop 304, second superconducting qubit loop 306, and Josephson junction 302 meet. Axis 308 also intersects a second node 312 at a second point where first superconducting qubit loop 304, second superconducting qubit loop 306, and Josephson junction 302 meet.

In some implementations, qubits 201, 202 in the portion of the superconducting quantum processor provided by circuit 200 can be embodied as superconducting flux qubit 300. In some implementations, qubits in quantum processor 126 of quantum computer 104 of computing system 100 may each be provided as superconducting flux qubit 300.

Galvanic Coupling of Superconducting Qubits

The design and selection of a topology (also referred to herein as the architecture) of an analog processor, that is, the arrangement defining the interconnection of qubits and couplers and/or other quantum devices, is an aspect of consideration in analog processor design. Particular topologies may be better suited to solving certain classes of problems than others. U.S. Pat. No. 8,772,759 provides examples of analog processor topologies.

A computational problem to be solved by a hybrid computing system can be mapped to a topological representation that is embedded onto an analog processor, such that the physical qubits in the analog processor can be used to solve the problem. In some implementations, the topological representation is in the form of a planar graph or a non-planar graph. In other implementations, the topological representation is a graph in the form of a plurality of vertices and one or more edges, the edges respectively connecting vertices of a respective pair of vertices. In another implementation, the topological representation is an interconnected graph of the same structure had by the topology of qubits.

In some implementations, a memory associated with a hybrid computing system, such as system memory 122 of computing system 100, includes logic to map a computational problem into at least one of a problem of equivalent, greater, or lesser complexity class. In some implementations, the logic that maps the computational problem onto an analog processor includes instructions for: mapping the computational problem to a topological representation, and embedding the topological representation onto quantum processor 126.

Many techniques for using quantum processors to solve computational problems involve finding ways to directly map a problem to the quantum processor itself. Given the generally fixed topology and/or fixed connectivity of hardware of a quantum processor, some classes of problem may advantageously benefit from the use of embedding techniques. Examples of embedding techniques are described in U.S. Pat. Nos. 7,984,012; 8,244,662; and 9,501,747. Examples of fixed topologies are described in greater detail in: U.S. Pat. Nos. 7,533,068; 9,170,278; 9,178,154; and, 11,507,871 (also published as U.S. Patent Application Publication No. 2019/0220771); and, International Patent Application PCT/US2022/038498 (published as International Patent Application Publication No. WO2023/009609) and International Patent Application PCT/US2021/031373 (published as International Patent Application Publication No. WO2021/231224).

Representations of particular problems might not be trivial to map onto a fixed topology of a quantum processor. For instance, since topologies of quantum processor might not be fully connected, some physical qubits might not be in direct communication with other physical qubits. As such, there are some instances where a problem having variables that are each represented by physical qubits cannot accurately express the relationships between all of the variables.

A topological representation may be an arrangement of logical qubits that describes relationships between problem variables in a straightforward manner. In some implementations, mapping the topological representation to the quantum processor requires mapping at least one of the logical qubits to a chain. A chain includes at least two physical qubits having a same state within the quantum processor, and a respective coupler to communicatively couple each pair of adjacent physical qubits. A chain of physical qubits may be used to represent one logical qubit, such that all connections between logical qubits in the topological representation are provided within the quantum processor. Herein, use of the term: “qubit” refers to a physical qubit within a quantum processor, unless explicitly specified otherwise.

A spatial limitation of qubits in a quantum processor is the ability to be coupled to another qubit at only a location of intersection therebetween. Through use of logical qubits comprising chains of physical qubits, there is an advantageous increase in relationships between variables that can be represented on the quantum processor due to intersection of each logical qubit with a larger number of physical qubits associated with other problem variables. Use of chains to map a topological representation to the quantum processor increases the number and scope of problems that can be solved using the quantum processor. However, there may be limitations associated with their use. By employing more than one physical qubit to express particular logical qubits, fewer physical qubits may be available in a quantum processor to represent additional problem variables. As such, this can reduce the complexity of problems that can be solved.

A chain of physical qubits that behave as a single logical qubit can improve connectivity between all physical qubits in a space occupied by a quantum processor. Connectivity of a physical qubit is distributed evenly along, and spatially limited to, a length of said physical qubit, due at least to an arrangement of physical devices (i.e., physical qubits and couplers) of the quantum processor; in other words, direct communicative coupling of a physical qubit is limited to locations at which said physical qubit crosses other physical qubits as determined by a topology of the quantum processor. An increase in connectivity of a single physical qubit through extension of its physical length may detrimentally result in a decrease of an energy scale of the quantum processor for the problem to be solved. A logical qubit comprising a chain of physical qubits can extend a physical area of the quantum processor topology that is reachable thereby without disadvantageously increasing a length of any singular physical qubit.

Chains, and particularly long chains, may also reduce the efficacy and/or efficiency of quantum computation. Solving problems including chains may be more computationally expensive and require additional resources compared to quantum computation without chains. Performing quantum computation with chains may take more time and/or may result in less accurate solutions.

In some implementations involving quantum-annealing processors, longer chains may freeze out during annealing before shorter chains, providing undesirably biased results. This effect may be limited by implementing a more complex annealing schedule to synchronize annealing trajectories of the chains using offsets. However, this may also increase the overall annealing time of the quantum processor.

An increased number and/or an increased length of chains in an embedding may reduce the performance of the quantum processor due to an increased likelihood of chain breakage. Chain breakage refers to occurrences of non-uniformity among states of physical qubits within the chain, such that the chain does not provide the intended connectivity between physical qubits of logical qubits. Weak coupling strengths of couplings between physical qubits of the chain can allow torque from local and/or coupled biases to detrimentally change a state of one or more physical qubits to break the chain. As chain breakage causes incorrect encoding of the relationships between problem variables, the resultant solutions to quantum computation may also be incorrect.

Effectiveness of chains of physical qubits as highly connected logical qubits can be limited by an intra-chain coupling strength relative to a coupling strength of couplings between a logical qubit and a representation of another problem variable (e.g., couplings between two logical qubits and/or couplings between a logical qubit and a physical qubit representative of a problem variable). In many systems, coupler structures have a maximum coupling strength for intra-chain coupling of physical qubits and coupling of physical qubits that represent different problem variables. As such, to increase the efficacy and limit breakage of chains comprising logical qubits, a coupling strength of couplers that connect physical qubits representative of different problem variables is decreased relative to a coupling strength of the intra-chain couplers. However, the reduction of coupling strength of the couplers that connect physical qubits representative of different problem variables directly results in disadvantageous reduction of an energy scale of the problem. A lower energy scale can lead to increased probability of thermal excitation within the quantum processor, which can degrade a quality of a solution determined thereby through quantum computation.

As such, it can be beneficial for a quantum processor to comprise couplers (e.g., coupler structures) having different maximum coupling strengths from other couplers. Each coupler having a higher maximum coupling strength can advantageously communicatively couple at least two qubits to behave as a logical qubit that is representative of a problem to be solved by the quantum processor, which can maintain a problem energy scale having a high enough value to mitigate detrimental effects on solution quality. Inclusion of couplers having higher maximum coupling strengths can provide the above-described advantages of chains of physical qubits, including reduction of spatial limitations of mapping problem variable relationships to the quantum processor topology, while mitigating errors associated with chain breakage.

In some implementations, strong couplings that yield improvements to qubit and spatial connectivity can be achieved through fully-galvanic coupler structures that directly superconductively extend between compound-compound Josephson junctions of at least two qubits of a quantum processor.

FIG. 3B is a schematic diagram of a circuit 320 comprising two superconducting flux qubits having a fixed galvanic coupling, in accordance with the present systems, devices, and methods. Circuit 320 comprises a first qubit 322a and a second qubit 322b that are superconductively communicatively coupled to one another via galvanic coupler 332 (shown in bolded lines in FIG. 3B).

In some implementations, a portion of a quantum processor shown as circuit 200 of FIG. 2 can include first and second qubits 322a, 322b in place of first and second qubits 201, 202. In such implementations, galvanic coupler 332 can be included in place of coupler 210 of FIG. 2.

Each of first and second qubits 322a, 322b is a superconducting flux qubit that respectively comprises a superconducting qubit loop 324a, 324b interrupted by a compound-compound Josephson junction (CCJJ) 326a, 326b. In some implementations, first and second qubits 322a, 322b are radio frequency superconducting quantum interference devices (rf-SQUIDs).

Each CCJJ 326a, 326b has a superconducting CCJJ loop 328a, 328b that is interrupted by two compound Josephson junctions (CJJs); i.e., CCJJ 326a includes superconducting CCJJ loop 328a that is interrupted by CJJs 330a and 330b, and CCJJ 326b includes superconducting CCJJ loop 328b that is interrupted by CJJs 330c and 330d. Superconducting qubit loops 324a, 324b and at least a portion of CCJJs 326a, 326b comprise at least one material that exhibits superconductive behavior at and below a respective critical temperature. In some implementations, the material comprises one or more of: aluminum, niobium, tantalum, and one or more other superconducting materials.

Although first and second qubits 322a, 322b are illustrated in FIG. 3B as comprising CCJJs 326a, 326b; however, this is not intended to be limiting. In other implementations, CCJJs 326a, 326b can each be replaced with a CJJ or Josephson junction (JJ).

Galvanic coupler 332 provides a superconductive electrical coupling between first and second qubits 322a, 322b. More particularly, galvanic coupler 332 is directly superconductively galvanically couples superconducting CCJJ loop 328a of first qubit 322a and superconducting CCJJ loop 328b of second qubit 322b.

Galvanic coupler 332 includes at least two lines of superconducting material directly galvanically coupled to superconducting CCJJ loop 328a of first qubit 322a and superconducting CCJJ loop 328b of second qubit 322b. The at least two traces of superconducting material comprise one or more materials that exhibit superconductive behavior at and below a respective critical temperature, such as: niobium, aluminum, tantalum, and other superconductive materials.

Each of the at least two lines of superconducting material can be one or more transmission lines, wires, or traces that are: deposited on a surface of a substrate, grown on a surface of a substrate, or otherwise formed as part of a superconductive integrated circuit. As well, each line of superconducting material can: include one or more segments of the superconducting material, can have any one of variety of shapes (e.g., straight, segmented, or crenulated with bends or angles which may or may not be right angles, curved, or arcuate), and can extend on one layer or through two or more layers of a multi-layer circuit board on which circuit 320 is fabricated (i.e., through vias).

The at least two lines of superconducting material form a direct, fully galvanic, closed superconductive path between superconductive CCJJ loops 328a, 328b of first and second qubits 322a, 322b. As galvanic coupler 332 provides fully galvanic coupling, galvanic coupler 332 does not include use of inductive interfaces to mediate coupling between first and second qubits 322a, 322b. Galvanic coupler 332 establishes communicative coupling between first and second qubits 322a, 322b having a coupling strength that exceeds that of a partially galvanic coupling or an inductive coupling therebetween. A mutual inductance value of galvanic coupler 332 is set to at least approximately a same inductance value of first and second qubits 322a, 322b to achieve the high coupling strength. Through direct galvanic coupling of first and second qubits 322a, 322b between their respective CCJ loops 328a, 328b, galvanic coupler 332 has a maximum coupling strength that exceeds a coupling strength of a coupler that galvanically interfaces with first and second qubits 322a, 322b at a different location; for instance, galvanic coupling between superconducting qubit loops 324a and 324b would have a lower coupling strength.

During performance of quantum computation, first and second qubits 322a, 322b connected by galvanic coupler 332 can be at least a portion of a chain of physical qubits that comprise a logical qubit. Through use of at least one galvanic coupler 332 in place of at least one partially or fully inductive coupler, the increase in relative coupling strength between physical qubits of the logical qubit can improve fidelity and significantly reduce a likelihood of obtaining invalid solutions to a problem to be solved by the quantum processor to which circuit 320 belongs.

The multi-level dynamics resulting from strong coupling between first and second qubits 322a, 322b of circuit 320 invalidates second order perturbation theory, such that first qubit 322a, second qubits 322b, and galvanic coupler 332 are operable as an aggregate structure that behaves as, and can be modeled by, a single physical qubit. Accordingly, when annealed as part of a logical qubit, first and second qubits 322a, 322b are operable as a single physical qubit while undergoing a change of state as opposed to two physical qubits that each undergo separate changes in state.

More particularly, the high coupling strength value provided by galvanic coupler 332 can enable first and second qubits 322a, 322b to behave as a single physical qubit having multiple superconducting loops, such as superconducting flux qubit 300 of FIG. 3A. For instance, a closed superconductive path formed by galvanic coupler 332 and CCJJs 326a, 326b of circuit 320 (FIG. 3B) can behave as Josephson junction 302 of superconducting flux qubit 300 (FIG. 3A), and superconducting qubit loop 324a, 324b of FIG. 3B can respectively behave as superconducting qubit loops 304, 306 of FIG. 3A that interrupt Josephson junction 302. In such implementations, a first superconducting path as described with respect to FIG. 3A can be provided by the superconducting qubit loop 324a and CCJJ 326a of first qubit 322a, and a second superconducting path can be provided by superconducting qubit loop 324b and CCJJ 326b of second qubit 322b.

The arrangement of closed superconducting loops (i.e., superconducting qubit loops 324a, 324b, CCJJ loops 328a, 328b, and the superconducting loop provided by galvanic coupler 332) in circuit 320 does not result in junctions formed at the periphery of qubits 322a, 322b. Circuit 320 does not suffer from trapped flux or unintended galvanic cycles, such that these phenomena do not degrade operation of qubits 322a, 322b and galvanic coupler 332, and quantum computation performed therewith is not negatively impacted.

In instances in which the at least two lines of superconducting material superconductively electrically connect CCJJs 326a, 326b located at a distance from one another, capacitive loading and coupler dynamics of galvanic coupler 332 may significantly impact the operation thereof. To reduce unwanted effects of capacitive loading, galvanic coupler 332 can optionally include one or more discrete inductors that interrupts its superconductive coupler loop. More particularly, one or more discrete inductors may be arranged in series with the superconductive coupler loop of galvanic coupler 332, which, in physical realizations, may have its own associated parasitic inductance. In some implementations, the one or more discrete inductors can be one or more inductive chokes. Although use of one or more discrete inductors can beneficially limit transmission of high frequencies thereacross to mitigate undesirable capacitive behavior therein, their inclusion may also result in reduced coupling strength of galvanic coupler 332.

In some implementations, a galvanic coupler that can directly superconductively couple CCJJs of at least two qubits can be programmable for selective coupling of said qubits and, optionally, selective determination of a coupling strength between the qubits. Such programmable galvanic couplers can be used to configure a topological representation of a variable, i.e., as at least a portion of a logical qubit, based on a specific corresponding problem representation of a problem to be solved on a quantum processor.

FIG. 3C is a schematic diagram of a circuit 340 comprising two flux qubits having a programmable galvanic coupling, in accordance with the present systems, devices, and methods. Circuit 340 comprises first qubit 322a and second qubit 322b that are superconductively communicatively coupled to one another via a programmable galvanic coupler 342 (shown in bolded lines in FIG. 3C). First and second qubits 322a, 322b are superconducting flux qubits that respectively comprise CCJJ 326a and CCJJ 326b as described with respect to FIG. 3B.

Programmable galvanic coupler 342 provides a superconductive electrical coupling between first and second qubits 322a, 322b. More particularly, programmable galvanic coupler 342 directly superconductively galvanically couples superconducting CCJJ loop 328a of first qubit 322a and superconducting CCJJ loop 328b of second qubit 322b.

Programmable galvanic coupler 342 of circuit 340 includes a superconductive coupler loop 344 interrupted by first and second coupler tunable connectors 346a and 346b, i.e., first and second coupler tunable connectors 346a, 346b are arranged in series with first and second qubits 322a, 322b. Superconductive coupler loop 344 includes at least two lines of superconducting material that comprise one or more materials that exhibit superconductive behavior at and below a respective critical temperature, such as: niobium, aluminum, tantalum, and other superconductive materials. The at least two traces of superconducting material and superconductive coupler loop 344 can be characterized in the same manner as described above with respect to galvanic coupler 332 of circuit 320 (FIG. 3B).

First and second coupler tunable connectors 346a, 346b are shown in FIG. 3C as CJJs; however, a person of skill in the art would understand that first and second coupler tunable connectors 346a, 346b can be one or more of: Josephson junctions, CCJJs, and other tunable inductors. Selective tuning of each tunable connector (346a, 346b) can modify an inductance thereof, which determines whether current passes therethrough. The selective tuning can be used to provide or configure a closed loop superconducting path between first and second qubits 322a, 322b in circuit 340 that provides strong, galvanic coupling therebetween.

First and second coupler tunable connectors 346a, 346b can be selectively tuned to be in an “ON” state to enable current flow therethrough and across superconductive coupler loop 344, such that first and second qubits 322a, 322b are galvanically coupled to one another. For instance, tuning the illustrated CJJs of first and second coupler tunable connectors 346a, 346b to have a very small Josephson inductances provides very low impedances across superconductive coupler loop 344. This results in substantially unimpeded current flow through programmable galvanic coupler 342 and thus strong coupling between first and second qubits 322a, 322b.

Alternatively, first coupler tunable connector 346a and/or second coupler tunable connector 346b can be selectively tuned to be in an “OFF”, such that superconductive coupler loop 344 behaves like an open circuit and current does not flow thereacross. In such configurations, programmable galvanic coupler 342 does not provide a closed loop superconductive path, and therefore no strong galvanic coupling, between CCJJs 326a, 326b of first and second qubits 322a, 322b.

Although FIG. 3C shows two coupler tunable connectors (346a, 346b), this is merely an example and is not intended to be limiting. In some implementations, programmable galvanic coupler 342 may include only one coupler tunable connector in series with superconductive coupler loop 344. In other implementations, programmable galvanic coupler 342 may include three or more tunable connector in series with superconductive coupler loop 344.

In other implementations, a programmable galvanic coupler may comprise one or more tunable connectors that shunt a superconductive coupler loop thereof.

FIG. 3D is a schematic of a circuit 360 comprising two flux qubits having an alternative programmable galvanic coupling, in accordance with the present systems, devices, and methods. Circuit 360 comprises first qubit 322a and second qubit 322b that are superconductively communicatively coupled to one another via a programmable galvanic coupler 362 (shown in bolded lines in FIG. 3D).

First and second qubits 322a, 322b are superconducting flux qubits that respectively comprise CCJJ 326a and CCJJ 326b as described with respect to FIG. 3B.

Programmable galvanic coupler 362 provides a fully galvanic, superconductive electrical coupling between first and second qubits 322a, 322b. Programmable galvanic coupler 362 of circuit 360 includes a superconductive coupler loop 364 and shunt line 368 that is interrupted by a coupler tunable connector 366.

Superconductive coupler loop 364 comprises a first coupler loop segment 364a and a second coupler loop segment 364b that each directly galvanically couple CCJJ 326a of first qubit 322a to CCJJ 326b of second qubit 322b. Each of first and second coupler loop segments 364a, 364b comprises at least one path (e.g., trace) of superconducting material that comprises one or more materials that exhibit superconductive behavior at and below a respective critical temperature. Superconductive coupler loop 364 can be characterized in the same manner as described above with respect to galvanic coupler 332 of FIG. 3B and superconductive coupler loop 344 of FIG. 3C.

Shunt line 368 extends between, and directly galvanically couples, first and second coupler loop segments 364a, 364b. Like each of first and second coupler loop segments 364a, 364b, shunt line 368 also comprises at least one path (e.g., trace) of one or more materials that exhibit superconductive behavior at and below a critical temperature. Coupler tunable connector 366 interrupts shunt line 368 such that a flow of current therethrough, and consequently across shunt line 368, is selectively configurable based on an inductance value of coupler tunable connector 366. In FIG. 3D, coupler tunable connector 366 is shown as a CJJ and has a Josepson inductance that is tunable to determine a shape of a superconductive path comprising first and second qubits 322a, 322b and some or all of programmable galvanic coupler 362. Coupler tunable connector 366 can be characterized in the same manner as described above with respect to first and second coupler tunable connectors 346a, 346b of FIG. 3C.

Though FIG. 3D shows circuit 360 as comprising one shunt line (368) interrupted by one CJJ (coupler tunable connector 366), a person of skill in the art would recognize that this is not intended to be limiting. In some implementations, shunt line 368 can be interrupted by a plurality of tunable connectors. In some implementations, superconductive coupler loop 364 of programmable galvanic coupler 362 can be shunted by two or more shunt lines, which can each be interrupted by a respective one or more tunable connectors.

In some implementations, programmable galvanic coupler 362 can include: at least one tunable connector interrupting superconductive coupler loop 364 (i.e., arranged in series with first and second qubits 322a, 322b), and at least one shunt line (368) interrupted by at least one coupler tunable connector (366) that shunts superconductive coupler loop 364.

FIG. 3E is a schematic diagram of a circuit 380 comprising two multi-loop superconducting flux qubits having a fixed galvanic coupling, in accordance with the present systems, devices, and methods. Circuit 380 comprises first multi-loop qubit 382a and a second superconducting qubit 382b that are superconductively communicatively coupled to one another via a galvanic coupler 390 (shown in bolded lines in FIG. 3E).

Each of first and second multi-loop qubits 382a, 382b can be characterized as described above with respect to superconducting flux qubit 300 of FIG. 3A. In circuit 380, first and second multi-loop qubits 382a, 382b include: respective CCJJs 386a, 386b; first superconducting qubit loops 384a, 384b; and, a second superconducting qubit loops 388a, 388b that are superconductively electrically coupled in parallel with first superconducting qubit loops 384a, 384b across CCJJs 386a, 386b. However, it is to be understood that first and second multi-loop qubits 382a, 382b can each include any number of superconducting qubit loops. All or a portion of first and second multi-loop qubits 382a, 382b comprise one or more materials that exhibit superconductive behavior at and below respective critical temperatures.

Galvanic coupler 390 includes at least two lines of superconducting material directly galvanically coupled to superconducting loop of CCJJ 386a of first multi-loop qubit 382a and superconducting loop of CCJJ 386b of second multi-loop qubit 382b. The at least two lines of superconducting material comprise one or more materials that exhibit superconductive behavior at and below respective critical temperatures. In some implementations, galvanic coupler 390 can be characterized in the same manner as galvanic coupler 332 of FIG. 3B.

Although galvanic coupler 390 is shown as a fixed coupler that comprises only a superconductive coupler loop in FIG. 3E, galvanic coupler 390 of circuit 380 can optionally be a programmable galvanic coupling between first and second multi-loop qubits 382a, 382b. In some such implementations, one or more tunable connectors can interrupt the superconductive coupler loop of galvanic coupler 390, such that the one or more tunable connectors are arranged in series with CCJJs 386a, 386b of first and second multi-loop qubits 382a, 382b. In some implementations, the superconductive coupler loop of galvanic coupler 390 can be shunted by one or more shunt lines, each of which is interrupted by one or more tunable connectors. In some implementations, galvanic coupler 390 can include a combination of tunable connectors that interrupt the superconductive coupler loop and tunable connectors that interrupt shunt lines arranged to shunt the superconductive coupler loop.

Galvanic couplers, such as galvanic couplers 332, 390 and programmable galvanic couplers 342, 362, can beneficially provide a communicative coupling having a strong coupling strength between at least two qubits, such as qubits 322a, 322b and multi-loop qubits 382a, 382b. The resultant strong, galvanic coupling therebetween can connect the qubits (322a, 322b or 382a, 382b) corresponding to a logical qubit of a topological representation of a problem to be solved by the quantum process. The high coupling strengths between qubits (322a, 322b or 382a, 382b) coupled to one another by the above-described galvanic couplers (332, 342, 362, 390) enables the quantum processor to have a high problem energy scale when performing computation. This advantageously mitigates sources of noise that negatively impact system dynamics and subsequent chain breakage, resulting in high quality solutions to a problem to be solved using the quantum processor.

As these galvanic couplers enable strong long-range coupling, the established logical qubit can comprise spatially separated physical qubits across a topology of a quantum processor to which at least one of circuits 320, 340, 360, and 380 belong, advantageously resulting higher connectivity between physical qubits of said quantum processor.

A logical qubit comprising at least one galvanic coupler (332, 342, 362, 390) can extend across at least a portion of the topology of the quantum processor and can be communicatively couplable to one or more physical or logical qubits that represent a different variable of a problem to be solved. Due to at least the relatively high coupling strength the logical qubit that includes the at least one galvanic coupler has an energy scale that exceeds an energy scale of a single qubit with a length having a same connectivity across the quantum processor topology. The connectivity of such a logical qubit can advantageously reduce limitations surrounding coupling of problem variables; for instance, although physical couplings are limited to physical qubits that intersect one another in the quantum processor topology, physical qubits chained together through the at least one galvanic coupler can advantageously provide the desired physical coupling without decreasing the problem energy scale.

Strong communicative coupling of qubits using at least one of galvanic coupler 332, 390 (FIGS. 3B and 3E) and/or programmable galvanic coupler 342, 362 (FIGS. 3C and 3D) can advantageously create logical qubits less prone to breakage and having a higher connectivity and energy scale than either: single physical qubits of a same length or logical qubits comprising physical qubits connected by couplers that are at least partially inductive (i.e., couplers that are not fully galvanic).

### Programmable Qubits Having Multiple Superconducting Loops

It is desirable for a topology of a quantum processor to enable mapping of a topological representation to qubits and couplers without the use of chains, with a minimal number of chains, and/or with chains having shortest possible lengths. To achieve this, one or more superconducting qubits may be selectively configured on a programmable superconducting circuit. A superconducting qubit may be configured to provide connectivity to one or more other superconducting qubits, such that the arrangement represents relationships between problem variables of a particular problem to be solved on the quantum processor.

The superconducting circuit may be programmed prior to an iteration of quantum computation to provide a qubit configuration that is best suited to the particular problem being solved using the quantum processor.

The superconducting circuit may be all or a portion of the quantum processor. In some implementations, several such superconducting circuits may be arranged as a lattice to provide a larger quantum processor topology.

To realize the above-noted characteristics, a superconducting circuit may include a set of superconductive arms, a set of compound Josephson junctions (CJJs), and a connection structure. Each CJJ of the set of CJJs may be electrically coupled to one of the superconductive arms, and the connection structure may be a network of superconductive arm connection lines interrupted by tunable connectors that connect the superconductive arms. The tunable connectors may be selectively tunable to control a flow of current through the connection structure, electrically coupling some of the superconductive arms, and configuring or establishing closed superconductive paths that form one or more qubits. Herein, a “closed superconductive path” refers to a closed superconductive path within the superconducting circuit that delineates a contiguous, unbroken electrical path of a qubit.

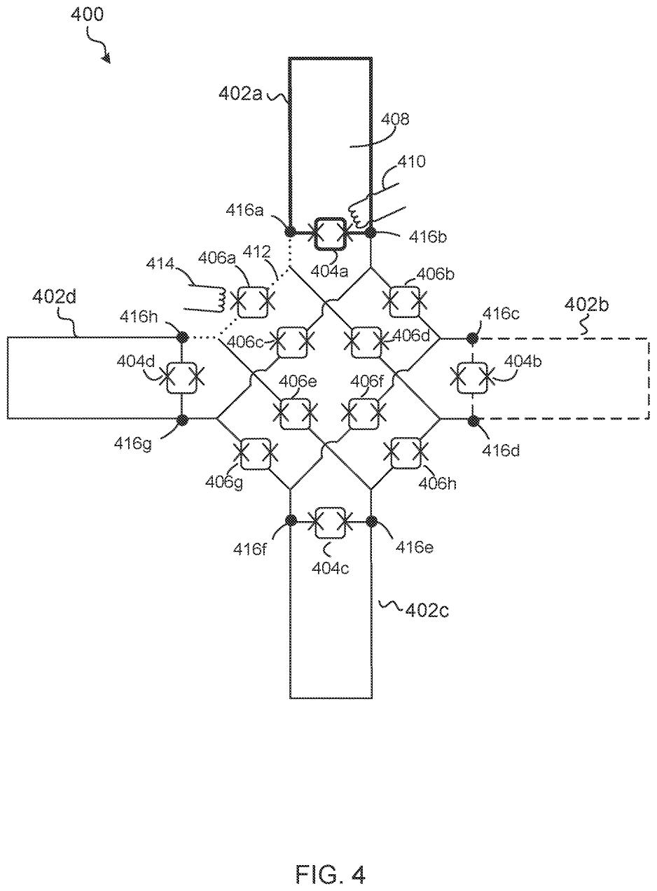

FIG. 4 illustrates a superconducting circuit 400 that is programmable to include one or more qubits, in accordance with the present systems, devices, and methods. Superconducting circuit 400 can provide a structure with multiple superconductive arms (402a, 402b, 402c, 402d, herein also collectively referenced as 402) that are connected to one another across a connection structure. The connection structure includes a set of superconductive arm connection lines (only superconductive arm connection line 412 is called out for visual clarity, and is shown as a dotted line) and a set of connecting CJJs (406a, 406b, 406c, 406d, 406e, 406f, 406g, 406h, herein also collectively referenced as 406) that each interrupt a respective superconductive arm connection line.

Selective tuning of at least some of the connecting CJJs of set of tunable connecting CJJs 406 can establish one or more closed superconductive paths that define one or more single-loop and/or multi-loop qubits. A superconducting loop of a qubit (also referred to as a superconducting qubit loop herein) is all or a portion of a closed superconductive path of the qubit, and comprises one or more traces of superconducting material (i.e., a superconductive arm 402 and/or one or more superconducting arm connection lines 412) and at least one flux qubit CJJ of a set of flux qubit CJJs (404a, 404b, 404c, 404d, herein also collectively referenced as 404). A single-loop qubit is a qubit having a closed superconducting path that includes one superconducting qubit loop. A multi-loop qubit is a qubit having a closed superconducting path that includes two or more superconducting qubit loops coupled across a flux qubit CJJ 404, and each superconducting qubit loop includes the components of a rf-SQUID.

In some implementations in which one or more multi-loop qubits are configured from superconducting circuit 400, a resulting multi-loop qubit includes the structure of superconducting flux qubit 300 (FIG. 3A), which has first and second superconducting qubit loops 304, 306 that each include, and are electrically coupled to one another across, Josephson junction 302. Although Josephson junction 302 of superconducting flux qubit 300 is shown as a CCJJ, it may alternatively be a CJJ like one of flux qubit CJJs 404 of superconducting circuit 400; alternatively, flux qubit CJJs 404 of superconducting circuit 400 can also be the CCJJs of Josephson junction 302. In some implementations, the one or more resulting multi-loop qubits may be a variation of superconducting flux qubit 300 having more than two superconducting qubit loops, and each pair of adjacent superconducting qubit loops are electrically coupled across a CJJ of set of flux qubit CJJs 404 that forms part of each of the closed superconductive qubit loops.

Additionally or alternatively, in some implementations in which one or more multi-loop qubits are configured from superconducting circuit 400, a resulting multi-loop qubit has a same structure as two physical qubits that are superconductively communicatively coupled to one another by a fully galvanic coupler, as shown in circuits 320, 340, and 360 (FIGS. 3B, 3C, and 3D). Although each of first and second qubits 322a, 322b are illustrated as CCJJs 326a, 326b, each of CCJJs 326a, 326b may alternatively be a CJJ like one of flux qubit CJJs 404 of superconducting circuit 400; alternatively, flux qubit CJJs 404 of superconducting circuit 400 can also be CCJJs of circuits 320, 340, and 360.

More particularly, superconducting circuit 400 can include two or more qubits (i.e., first qubit 408 of FIG. 4 may be akin to qubits 322a, 322b of FIGS. 3B, 3C, and 3D), each with a closed superconductive qubit loop comprising a superconductive arm (402a, 402b, 402c, 402d) and a corresponding flux qubit CJJ (404a, 404b, 404c, 404d). At least two of these qubits are galvanically coupled to flux qubit CJJs 404 of one another via superconducting arm connection lines 412 interrupted by CJJs of set of connecting CJJs 406, which provides a structure similar to programmable galvanic coupler 342 of FIG. 3C (i.e., superconductive coupler loop 344 interrupted by first and second coupler tunable connectors 346a and 346b couples first and second qubits 322a, 322b via respective CCJJs 326a, 326b).

In some implementations, superconducting circuit 400 may configured to implement qubits 201 and 202 of the portion of a superconducting processor of circuit 200. In some implementations, superconducting circuit 400 may provide a portion of quantum processor 126 of computing system 100.

Superconducting circuit 400 includes a first superconductive arm 402a, a second superconductive arm 402b, a third superconductive arm 402c, and a fourth superconductive arm 402d.

Each superconductive arm of set of superconductive arms 402 can be a trace of superconductive material that extends between two connection nodes in an open shape. Notably, the connection nodes can be part of the trace of superconductive material, for instance endpoints of the traces or even intermediate points in the traces. In FIG. 4, superconductive arms 402 are each substantially rectangular with an open portion, but can have any suitable open arced or bent shape. For example, in alternative implementations, superconductive arms 402 may be traces of superconducting material having a U shape and/or an open shape that is substantially rectangular, circular, oblong, or curved rectangular.

In FIG. 4, first superconductive arm 402a is a trace of superconducting material extending between a first connection node 416a and a second connection node 416b in a U shape. Second superconductive arm 402b is a trace of superconducting material extending between a third connection node 416c and a fourth connection node 416d in a U shape. Third superconductive arm 402c is a trace of superconducting material extending between a fifth connection node 416e and a sixth connection node 416f in a U shape. Fourth superconductive arm 402d is a trace of superconducting material extending between a seventh connection node 416g and an eighth connection node 416h in a U shape.

Each trace of superconducting material can include one or more segments of superconducting material, which can have any one of variety of shapes (e.g., straight, segmented, or crenulated with bends or angles which may or may not be right angles, curved, or arcuate), and which can extend on one layer or through two or more layers of a multi-layer circuit board on which superconducting circuit 400 is fabricated, for instance including vias.

For visual clarity as to the superconducting trace that is encompassed as part of a superconductive arm herein, second superconductive arm 402b is shown in FIG. 4 by dashed lines.

In FIG. 4, superconductive arms 402 are shown as being equal in size to one another. However, this is merely an example and dimensions of superconductive arms 402 and not intended to be limiting. Superconductive arms 402 can be substantially similar or even identical in size to one another, or each superconductive arm of superconductive arms 402 can dimensioned differently than one or more other superconductive arms 402.

In the example implementation of FIG. 4, a major axis each one of superconductive arms 402 is substantially perpendicular to major axes of two other superconductive arms 402 and parallel to a major axis one other superconductive arm. For instance, first superconductive arm 402a has a major axis that is arranged at a 90 degree angle from major axes of second and fourth superconductive arms 402b, 402d and parallel to a major axis of third superconductive arm 402c. This arrangement is merely an example, and is not intended to be limiting. Superconductive arms 402 can be oriented with respect to one another in any suitable manner in two-dimensional space, as long as each one can be communicatively coupled to all other superconductive arms via set of connecting CJJs 406.

Shapes and sizes of superconductive arms 402 of superconducting circuit 400 can accommodate a desired architecture of a superconducting processor.

Each superconductive arm 402 is electrically coupled to a flux qubit CJJ of set of flux qubit CJJs 404. First, second, third, and fourth superconductive arms 402a, 402b, 402c, 402d are respectively coupled to first, second, third, and fourth flux qubit CJJs 404a, 404b, 404c, 404d to form a respective superconducting qubit loops. More particularly, each CJJ of set of flux qubit CJJs 404 is electrically arranged between a pair of connection nodes that terminates a respective superconductive arm. For instance, first flux qubit CJJ 404a is electrically arranged between first and second connection nodes 416a, 416b of first superconductive arm 402a.

CJJs of set of flux qubit CJJs 404 can be any one of: Josephson junctions, CJJs, and CCJJs. A CJJ of set of flux qubit CJJs 404 at least closes off a superconductive arm 402 to form a first superconducting qubit loop, and can also close off a second superconducting qubit loop coupled to the first superconducting qubit loop. Herein, closing off a superconductive arm refers to closing the open shape trace of superconducting material to form a closed superconductive path through which current can flow.

Each flux qubit CJJ (404a, 404b, 404c, 404d) can receive a flux signal that determines behavior of the qubit during quantum computation from a flux qubit CJJ interface 410. Although only one flux qubit CJJ interface 410 coupled to first flux qubit CJJ 404a is shown in FIG. 4, it is to be understood that each flux qubit CJJ (404a, 404b, 404c, 404d) is coupled to a respective flux qubit CJJ interface 410. Flux qubit CJJ interface 410 is depicted as an inductive interface and may for example take the form of interface 221 (FIG. 2), which may receive a control signal generated by control circuitry, such as by devices of qubit control system 130. In alternative implementations, flux qubit CJJ interface 410 may be an analog line that is electrically coupled to the flux qubit CJJ (404a, 404b, 404c, 404d). The received control signals can be used to modify the potential energy landscape of a resultant single-loop or multi-loop qubit formed by at least the flux qubit CJJ (404a, 404b, 404c 404d).

In adiabatic and/or annealing quantum computing, performing quantum computation includes raising an energy barrier of a qubit to create a double-well potential such that the probability of finding the qubit in either classical state is equal. The control signals received by set of flux qubit CJJs 404 can be used to apply a bias to the one or more resultant qubits to tune the double-well potential as desired for a particular application.

The connection structure of superconducting circuit 400 can include set of superconductive arm connection lines 412, each which is interrupted by a respective CJJ of set of tunable connecting CJJs 406.

Superconductive arm connection lines 412 can be superconductive traces that can have any one of variety of shapes, and which can extend on one layer or through two or more layers of a multi-layer circuit board on which superconducting circuit 400 is fabricated, for instance including vias. Each superconductive arm connection line 412 can extend between a connection node of one superconductive arm and a connection node of another superconductive arm. For example, called out superconductive arm connection line 412 extends between first connection node 416a of first superconductive arm 402a and eighth connection node 416h of fourth superconductive arm 402d.

In some implementations, there may be a superconductive arm connection line between each connection node of a superconductive arm and a connection node belonging to each of the other superconductive arms of set of superconductive arms 402. In such implementations, superconducting circuit 400 includes a fully connected network between the superconductive arms.

Set of connecting CJJs 406 that interrupt the set of superconductive arm connection lines 412 is illustrated as including eight CJJs: first connecting CJJ 406a, second connecting CJJ 406b, third connecting CJJ 406c, fourth connecting CJJ 406d, fifth connecting CJJ 406e, sixth connecting CJJ 406f, seventh connecting CJJ 406g, and eight connecting CJJ 406h. In superconducting circuit 400, each superconductive arm 402 can optionally be in electrical communication with each CJJ of set of connecting CJJs 406, and superconducting paths can optionally be established between any ones of superconductive arms 402 and CJJs of set of connecting CJJs 406.

Each connecting CJJ of set of connecting CJJs 406 can be selectively tuned to be in an “ON” state or an “OFF” state. In the “ON” state, current flows through a connecting CJJ of the set of connecting CJJs 406 across a superconductive arm connection line 412 of which it interrupts, providing a superconducting path between two superconductive arms 402. In the “OFF” state, a CJJ of the set of connecting CJJs 406 does not enable current flow across its respective superconductive arm connection line 412 between connection nodes of two superconductive arms 402. By tuning set of connecting CJJs 406, superconducting paths can be selectively established between connection nodes of superconductive arms 402. Selective tuning of each CJJ of set of connecting CJJs 406 can modify a Josephson inductance of a respective CJJ, thereby determining whether current passes through the respective CJJ. For instance, tuning a CJJ of set of connecting CJJs 406 to have a near-infinite Josephson inductance provides a high impedance, resulting in that CJJ being in the “OFF” state. Conversely, tuning a CJJ of set of connecting CJJs 406 to have a small Josephson inductance provides a low impedance, resulting in that CJJ being in the “ON” state.

Tuning the Josephson inductance of a CJJ of set of connecting CJJs 406 may be based on a control signal that has been generated by control circuitry, such as by devices of qubit control system 130 (FIG. 1). Each CJJ may receive a respective control signal via a connecting CJJ interface 414. Although only one connecting CJJ interface 414 coupled to first connecting CJJ 406a is shown in FIG. 4, it is to be understood that each connecting CJJ (406a, 406b, 406c, 406d, 406e, 406f, 406g, 406h) is coupled to a respective connecting CJJ interface 414. Connecting CJJ interface 414 is depicted as an inductive interface in FIG. 4, through which a control signal can be provided from connecting CJJ interface 414 to first connecting CJJ 406a in terms of flux quanta. As flux quanta is proportional to Josephson inductance, a control signal that increases flux quanta in first connecting CJJ 406a can set first connecting CJJ 406a to the “OFF” state. In alternative implementations, each connecting CJJ interface 414 can be an analog line that is electrically coupled to a respective CJJ of set of connecting CJJs 406, and a control signal that decreases a Josephson critical current in first connecting CJJ 406a can set first connecting CJJ 406a to the “OFF” state.

A closed superconductive path including one superconductive arm 402 and one CJJ of set of flux qubit CJJs 404 provides a single-loop qubit.

In an implementation where all CJJs of set of connecting CJJs 406 are tuned to be in the “OFF” state, superconducting circuit 400 provides four single-loop, uncoupled rf-SQUID qubits. For instance, in such an implementation, a first qubit 408 can have a superconducting qubit loop shown by bolded lines in FIG. 4, which is delineated by the open shape of first superconductive arm 402a and at least a portion of first flux qubit CJJ 404a. The closed superconductive path of first qubit 408 includes only this superconducting qubit loop. In some implementations, each Josephson junction of first flux qubit CJJ 404a may alternatively be implemented as a Josephson junction or CCJJ. Although the three other uncoupled rf-SQUID qubits are not called out in FIG. 4, these may be formed in a similar manner by the other superconductive arms (402b, 402c, 402d) and their respective flux qubit CJJs of set of flux qubit CJJs (404b, 404c, 404d).

Different qubit arrangements can be selectively provided by turning “ON” and “OFF” CJJs of set of connecting CJJs 406. In some implementations, different qubit arrangements can include one or more multi-loop qubits. A multi-loop qubit of superconducting circuit 400 can have a closed superconductive path including: at least two superconductive arms 402; at least two CJJs of set of flux qubit CJJs 404; and, at least two superconductive arm connection lines 412 interrupted by respective CJJs of set of connecting CJJs 406 that extend between the at least two superconductive arms 402. One or more multi-loop qubits can be configured by setting states of CJJs of set of connecting CJJs 406 to be “ON” or “OFF” to determine current flow thereacross. A particular one of a plurality of multi-loop qubit arrangements can be configured based on which CJJs of set of connecting CJJs 406 are tuned to be “ON” and “OFF”.

Selectively providing different qubit arrangements can thereby enable different arrangements of unit cells as part of the superconducting processor architecture. Superconducting circuit 400 can be tiled within a superconducting processor by repeating its structure in a lattice. The tiled superconducting circuits can be configured to provide a desired topology. The topology may be one of those having unit cells as described in U.S. Pat. Nos. 7,533,068; 9,170,278; 9,178,154; and, 11507871 (published as U.S. Patent Application Publication No. 2019/0220771); U.S. Provisional Patent Application No. 63/227,395; and International Patent Application PCT/US2022/038498 (published as International Patent Application Publication No. WO2023/009609) and International Patent Application PCT/US2021/031373 (published as International Patent Application Publication No. WO2021/231224 and WO2023/009609 to provide a topology as described therein. Alternatively, the topology may consist of superconducting circuits that are configured to provide qubits in a different arrangement. Each of the tiled superconducting circuits can be configured to provide same or different configurations of qubits to one another. Therefore, a superconducting processor consisting of a repeating lattice of superconducting circuit 400 provides a programmable architecture that can have an exponential number of qubit configurations.

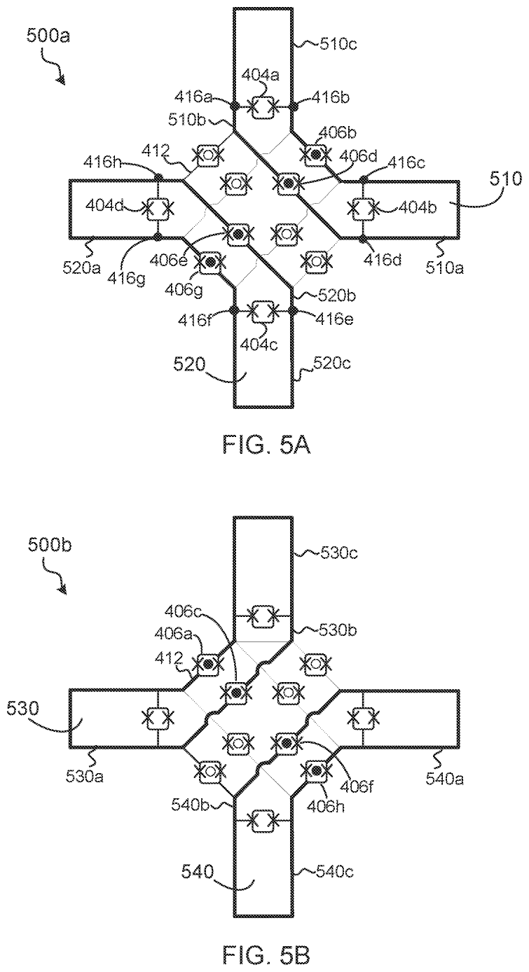

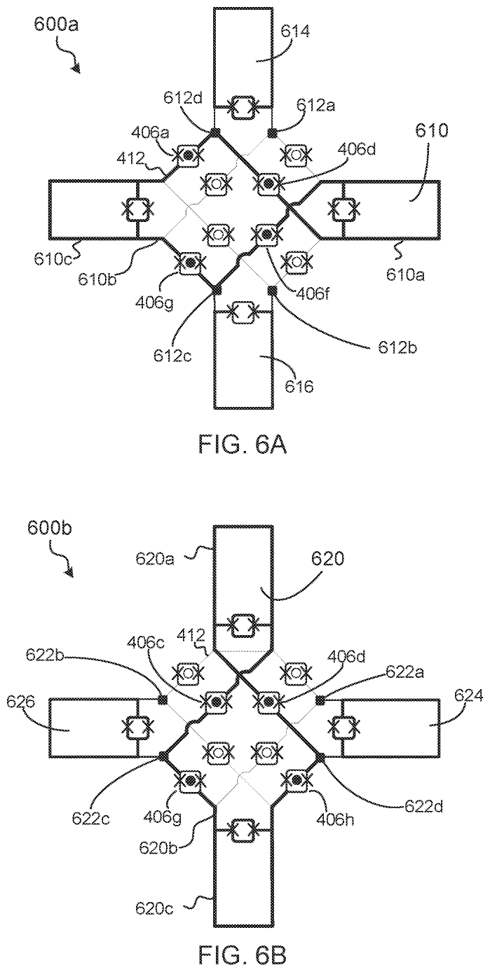

Examples of qubit architectures or topologies configured using superconducting circuit 400 are shown in FIGS. 5 and 6.

FIG. 5A illustrates the superconducting circuit of FIG. 4 programmed to provide flux qubits in one configuration. Here, a superconducting circuit configuration 500a illustrates one arrangement provided by selectively tuning the CJJs of set of connecting CJJs 406 of superconducting circuit 400. As such, superconducting circuit configuration 500a includes all of the elements of superconducting circuit 400 in FIG. 4, though not all elements are called out in FIG. 5A for visual clarity.

Herein, the orientations of qubits configured on superconducting circuit 400 are described by the superconductive arms 402 included as part of each qubit, which are described based on their arrangement in the plane of the pages of FIGS. 4-6 and 9. First superconductive arm 402a and third superconductive arm 402c are arranged substantially vertically on the pages and are collectively referred to as having a “vertical” orientation. Individually, first superconductive arm 402a is referred to as having an “up” orientation and third superconductive arm402c is referred to as having a “down” orientation. Second superconductive arm 402b and fourth superconductive arm 402d are arranged substantially horizontally on the pages and are collectively referred to as having a “horizontal” orientation. Individually, second superconductive arm 402b is referred to as having a “right” orientation and fourth superconductive arm 402d is referred to as having a “left” orientation.

Superconducting circuit configuration 500a includes two multi-loop superconducting qubits: a first qubit 510 and a second qubit 520. Based on the selective tuning of CJJs of set of connecting CJJs 406, first qubit 510 includes second superconductive arm 402b and first superconductive arm 402a. As such, first qubit 510 is oriented as a “right-up” qubit. Second qubit 520 is a“ left-down” qubit and includes fourth superconductive arm 402d and third superconductive arm 402c.

To arrive at a particular superconducting circuit configuration, the states of each CJJ of set of connecting CJJs 406 are set as one of “ON” or “OFF” to establish the closed superconductive paths within superconducting circuit 400. In FIGS. 5, 6, 7B, 7C, 8B, and 9, each connecting CJJ is shown with a circle in the center of its schematic representation. CJJs having unfilled (i.e., white) circles are indicative of CJJs that have been tuned to the “OFF” state. Superconductive arm connection lines 412 (only one called out) interrupted by connecting CJJs in the “OFF” state are shown as thin lines, indicating that these superconductive arm connection lines 412 do not comprise part of a closed superconductive path.

Conversely, connecting CJJs having filled (i.e., black) circles are indicative of CJJs that have been tuned to the “ON” state. Superconductive arm connection lines 412 interrupted by connecting CJJs in the “ON” state are shown as thick lines, indicating that these superconductive arm connection lines 412 form part of a closed superconductive path. In FIGS. 5, 6, 7B, 7C, 8B, and 9, only connecting CJJs in the “ON” state are called out for clarity.

To program superconducting circuit 400 to configure first qubit 510, second connecting CJJ 406b and fourth connecting CJJ 406d are set to the “ON” state, and current flows between first superconductive arm 402a and second superconductive arm 402b via: superconductive arm connection line 412 interrupted by second connecting CJJ 406b that extends between second connection node 416b and third connection node 416c; and, superconductive arm connection line 412 interrupted by fourth connecting CJJ 406d that extends between first connection node 416a and fourth connection node 416d. First, third, sixth, and eighth connecting CJJs 406a, 406c, 406f, and 406h (FIG. 4) are set to the “OFF” state, inhibiting current flow and electrical communication between first and second superconductive arms 402a, 402b and third and fourth superconductive arms 402c, 402d.

Resultantly, first qubit 510 includes three superconducting first qubit loops. The three superconducting first qubit loops are as follows: first superconducting first qubit loop 510a consisting of: second superconductive arm 402b (FIG. 4) and at least a portion of second flux qubit CJJ 404b (FIG. 4); second superconducting first qubit loop 510b consisting of: superconductive arm connection lines 412 interrupted by second and fourth connecting CJJs 406b, 406d (FIG. 4), and at least a portion of first and second flux qubit CJJs 404a, 404b (FIG. 4); and third superconducting first qubit loop 510c consisting of: first superconductive arm 402a (FIG. 4) and at least a portion of first flux qubit CJJ 404a (FIG. 4).

To program superconducting circuit 400 to configure second qubit 520, fifth connecting CJJ 406e and seventh connecting CJJ 406g are set to the “ON” state, and current flows between third superconductive arm 402c and fourth superconductive arm 402d via: superconductive arm connection line 412 interrupted by fifth connecting CJJ 406e that extends between fifth connection node 416e and eighth connection node 416h; and, superconductive arm connection line 412 interrupted by seventh connecting CJJ 406g that extends between sixth connection node 416f and seventh connection node 416g.

Second qubit 520 includes: a first superconducting second qubit loop 520a consisting of: fourth superconductive arm 402d (FIG. 4) and at least a portion of fourth flux qubit CJJ 404d (FIG. 4); a second superconducting second qubit loop 520b consisting of: superconductive arm connection lines 412 interrupted by fifth and seventh connecting CJJs 406e, 406g (FIG. 4), and at least a portion of each of third and fourth flux qubit CJJs 404c, 404d (FIG. 4); and, third superconducting second qubit loop 520c consisting of: third superconductive arm 402c (FIG. 4), and at least a portion of third flux qubit CJJ 404c (FIG. 4).

FIG. 5B illustrates the superconducting circuit of FIG. 4 programmed to provide two qubits in a different configuration. A superconducting circuit configuration 500b illustrates an arrangement of qubits provided by selectively tuning the CJJs of set of connecting CJJs 406 of superconducting circuit 400 in a different manner than as described for superconducting circuit configuration 500a.

Superconducting circuit configuration 500b includes two multi-loop superconducting qubits: a first qubit 530 and a second qubit 540. Based on the selective tuning of CJJs of set of connecting CJJs 406, first qubit 530 includes fourth superconductive arm 402d (FIG. 4) and first superconductive arm 402a (FIG. 4). As such, first qubit 510 is oriented as a “left-up” qubit. Second qubit 540 is a “right-down” qubit and includes second superconductive arm 402b (FIG. 4) and third superconductive arm 402c (FIG. 4).

To program superconducting circuit 400 to configure first qubit 530, first connecting CJJ 406a and third connecting CJJ 406c are set to the “ON” state, and current flows between fourth superconductive arm 402d (FIG. 4) and first superconductive arm 402a (FIG. 4) via: superconductive arm connection line 412 interrupted by first connecting CJJ 406a that extends between first connection node 416a and eighth connection node 416h; and, superconductive arm connection line 412 interrupted by third connecting CJJ 406c that extends between second connection node 416b and seventh connection node 416g.

Second, fourth, fifth, and eighth connecting CJJs 406b, 406d, 406e, and 406g (FIG. 4) are set to the “OFF” state, inhibiting current flow across superconductive arm connection lines 412 that extend between first and fourth superconductive arms 402a, 402d (FIG. 4) and second and third superconductive arms 402b, 402c (FIG. 4).

First qubit 530 includes: a first superconducting first qubit loop 530a consisting of: fourth superconductive arm 402d (FIG. 4) and at least a portion of fourth flux qubit CJJ 404d (FIG. 4); a second superconducting first qubit loop 530b consisting of: superconductive arm connection lines 412 interrupted by first and third connecting CJJs 406a, 406c (FIG. 4), and at least a portion of each of fourth and first flux qubit CJJs 404d, 404a (FIG. 4); and, third superconducting first qubit loop 530c consisting of: first superconductive arm 402a (FIG. 4) and at least a portion of first flux qubit CJJ 404a (FIG. 4).

To program superconducting circuit 400 to configure second qubit 540, sixth connecting CJJ 406f and eighth connecting CJJ 406h are set to the “ON” state, and current flows between second superconductive arm 402b (FIG. 4) and third superconductive arm 402c (FIG. 4) via: superconductive arm connection line 412 interrupting sixth connecting CJJ 406f that extends between third connection node 416c and sixth connection node 416f; and, superconductive arm connection line 412 interrupting eighth connecting CJJ 406h that extends between fourth connection node 416d and fifth connection node 416e (FIG. 4).

Second qubit 540 includes: a first superconducting second qubit loop 540a consisting of: second superconductive arm 402b (FIG. 4) and at least a portion of second flux qubit CJJ 404b (FIG. 4); a second superconducting second qubit loop 540b consisting of: superconductive arm connection lines interrupted by sixth and eighth connecting CJJs 406f, 406h (FIG. 4), and at least a portion of each of second and third flux qubit CJJs 404b, 404c (FIG. 4); and, third superconducting second qubit loop 540c consisting of: third superconductive arm 402c (FIG. 4) and at least a portion of third flux qubit CJJ 404c (FIG. 4).

Although superconducting circuit configurations 500a and 500b each include two multi-loop qubits, there are arrangements in which superconducting circuit 400 may also be configured to provide one multi-loop qubit and two single-loop qubits. Some of these arrangements are shown in FIGS. 6A and 6B.

FIG. 6A illustrates the superconducting circuit of FIG. 4 programmed to provide one multi-loop qubit and two single-loop qubits in one configuration. A superconducting circuit configuration 600a illustrates the result of selectively tuning set of connecting CJJs 406 of superconducting circuit 400 to provide one multi-loop qubit oriented as a “horizontal” qubit (herein referred to as horizontal qubit 610).

Programming superconducting circuit 400 to configure horizontal qubit 610 includes tuning first, fourth, sixth, and seventh connecting CJJs 406a, 406d, 406f, and 406g to the “ON” state, and tuning the remaining connecting CJJs to the “OFF” state. This establishes a closed superconductive path consisting of first, second, and third horizontal qubit loops 610a, 610b, and 610c, respectively. First horizontal qubit loop 610a includes: second superconductive arm 402b (FIG. 4) and at least a portion of second flux qubit CJJ 404b (FIG. 4). Second horizontal qubit loop 610b electrically couples first and third horizontal qubit loops 610a, 610c, and includes: superconductive arm connection lines 412 interrupted by first, fourth, sixth, and seventh connecting CJJs 406a, 406d, 406f, 406g (FIG. 4), and at least a portion of each of second and fourth flux qubit CJJs 404b, 404d (FIG. 4). Third horizontal qubit loop 610c includes: fourth superconductive arm 402d (FIG. 4) and at least a portion of fourth flux qubit CJJ 404d (FIG. 4).

The “OFF” states of second and third connecting CJJs 406b and 406c (FIG. 4) remove paths for current to flow to point or node 612a, thereby excluding first superconductive arm 402a (FIG. 4) from the closed superconductive path of horizontal qubit 610. Likewise, third superconductive arm 402c (FIG. 4) is excluded from the closed superconductive path of horizontal qubit 610 due to the “OFF” states of sixth and eighth connecting CJJs 406e and 406h (FIG. 4) that removes paths for current to flow to point or node 612b.

In FIG. 6A, the configuration of horizontal qubit 610 includes the tuning of particular connecting CJJs to the “OFF” state such that current does not flow through points or nodes 612a and 612b, which are not in electrical communication with the closed superconductive path of horizontal qubit 610. However, this is only one example arrangement of a horizontal qubit configured on superconducting circuit 400.

In alternative arrangements, different combinations of CJJs of set of connecting CJJs 406 can be tuned to the “OFF” and “ON” states to provide different horizontal superconducting paths. In an implementation, second, third, fifth, and eighth connecting CJJs 406b, 406c, 406e, 406h (FIG. 4) can be set to the “ON” state, and the remaining connecting CJJs can be set to the “OFF” state. This would provide an arrangement with a horizontal superconducting path flipped along a longitudinal axis of the page of FIG. 6A relative to superconducting circuit configuration 600a. In this implementation, points or nodes 612a and 612b are part of the horizontal superconducting path but nodes 612c and 612d are not, thereby preventing electrical coupling of the vertical superconductive arms (402a, 402c, FIG. 4).

In other alternative implementations, set of connecting CJJs can be tuned in any way such that: a closed superconductive path of a multi-loop horizontal qubit includes: closed loops formed by second and fourth superconductive arms 402b, 402d (FIG. 4); one of points or nodes 612a and 612d is not in electrical communication with the closed superconductive path; and, one of nodes 612b and 612c is not in electrical communication with the closed superconductive path.

In addition to horizontal qubit 610, superconducting circuit configuration 600a also includes a first single-loop qubit 614 and a second single-loop qubit 616. First single-loop qubit 614 includes: first superconductive arm 402a (FIG. 4) and at least a portion of first flux qubit CJJ 404a (FIG. 4). Second single-loop qubit 616 includes: third superconductive arm 402c (FIG. 4) and at least a portion of third flux qubit CJJ 404c (FIG. 4).

FIG. 6B illustrates the superconducting circuit of FIG. 4 programmed to provide one multi-loop qubit and two single-loop qubits in a different configuration. A superconducting circuit configuration 600b illustrates the result of selectively tuning set of connecting CJJs 406 of superconducting circuit 400 to provide one multi-loop qubit oriented as a “vertical” qubit (herein referred to as vertical qubit 620).

Programming superconducting circuit 400 to configure vertical qubit 620 includes tuning third, fourth, seventh, and eighth connecting CJJs 406c, 406d, 406g, and 406h to the “ON” state, and tuning the remaining connecting CJJs to the “OFF” state. This establishes a closed superconductive path of vertical qubit 620 consisting of first, second, and third vertical qubit loops 620a, 620b, and 620c, respectively. First vertical qubit loop 620a includes: first superconductive arm 402a (FIG. 4) and at least a portion of first flux qubit CJJ 404a (FIG. 4).

Second vertical qubit loop 620b electrically couples first and third vertical qubit loops 610a, 610c, and includes: superconductive arm connection lines 412 interrupted by third, fourth, seventh, and eighth connecting CJJs 406c, 406d, 406g, 406h (FIG. 4), and at least a portion of each of first and third flux qubit CJJs 404a, 404c (FIG. 4). Third horizontal qubit loop 610c includes: third superconductive arm 402c (FIG. 4) and at least a portion of third flux qubit CJJ 404c (FIG. 4).

The “OFF” states of second and sixth connecting CJJs 406b and 406f (FIG. 4) remove paths for current to flow to point or node 622a, thereby excluding second superconductive arm 402b (FIG. 4) from the closed superconductive path of vertical qubit 620. Likewise, fourth superconductive arm 402d (FIG. 4) is excluded from the closed superconductive path due to the “OFF” states of first and fifth connecting CJJs 406a and 406e (FIG. 4) that inhibit current from flowing to point or node 622b.

In FIG. 6B, the configuration of vertical qubit 620 includes the tuning of particular connecting CJJs to the “OFF” state such that points or nodes 622a and 622b are not in electrical communication with the closed superconductive path of vertical qubit 620. However, this is only one example arrangement of a vertical multi-loop qubit configured on superconducting circuit 400.

In alternative arrangements, different combinations of CJJs of set of connecting CJJs 406 can be tuned to the “OFF” and “ON” states to provide different closed superconductive paths of a multi-loop vertical qubit. Set of connecting CJJs can be tuned in any way such that: a closed superconductive path includes: first and third superconductive arms 402a, 402c (FIG. 4); one of points or nodes 622a and 622d is not in electrical communication with the closed superconductive path; and, one of points or nodes 622b and 622c is not in electrical communication with the closed superconductive path.

As well, superconducting circuit configuration 600b also includes a first single-loop qubit 624 and a second single-loop qubit 626. First single-loop qubit 624 includes: second superconductive arm 402b (FIG. 4) and at least a portion of second flux qubit CJJ 404b (FIG. 4). Second single-loop qubit 616 includes: fourth superconductive arm 402d (FIG. 4) and at least a portion of fourth flux qubit CJJ 404d (FIG. 4).

In addition to the described horizontal and vertical qubits, superconducting circuit 400 can be configured to provide one multi-loop qubit and at least two single-loop qubits in other arrangements. For instance, superconducting circuit 400 can be configured to include only one of: a “right-up” qubit like first qubit 510 of superconducting circuit configuration 500a, where only fifth and seventh connecting CJJs 406e, 406g are in the “ON” state; a “left-down” qubit like second qubit 520 of superconducting circuit configuration 500a, where only second and fourth connecting CJJs 406b, 406d are in the “ON” state; a “left-up” qubit like first qubit 530 of superconducting circuit configuration 500b, where only first and third connecting CJJs 406a, 406c are in the “ON” state; or a “right-down” qubit like second qubit 540 of superconducting circuit configuration 500b, where only sixth and eighth connecting CJJs 406f, 406h are in the “ON” state.

Any CJJ of set of connecting CJJs 406 that is included as part of one of qubits 510, 520, 530, 540, 610, and 620 can optionally be operable as an L-tuner. Selective tuning of the “ON” CJJs of set of connecting CJJs 406 can compensate for discrepancies in qubit inductance of each qubit, or a set of qubits, configured on superconducting circuit 400. Use of CJJs as part of an L-tuner structure is described in: U.S. Pat. No. 8,536,566, U.S. Patent Application Publication No. 2023/0027682, and International Patent Application Publication No. PCT/US2022/081515 (published as WO2023/219656). Use of “on” CJJs of set of connecting CJJs 406 may reduce a number of additional L-tuners required, or eliminate the need for additional L-tuners, within an analog processor.

Configuring an arrangement of qubits on superconducting circuit 400 may improve the results of quantum computation. The arrangement of qubits can be advantageously programmed to best suit a structure of a particular problem to be solved. The programmability of the qubit configurations is enabled by set of connecting CJJs 406 (FIG. 4). The ability to tune set of connecting CJJs 406 to an “ON” or “OFF” state allows selective electrical coupling of pairs of superconductive arms of set of superconductive arms 402 to determine an orientation of a multi-loop qubit.

Set of connecting CJJs 406 (FIG. 4) can be used to program superconducting circuit 400 such that qubits representing problem variables can be configured to be connected to qubits representing interrelated problem variables. This may reduce the complexity of embedding a topological representation of the problem onto the quantum processor, thereby reducing a number of chains and/or lengths of chains when mapping problem variables as qubits.

The configurability of qubits on superconducting circuit 400 (FIG. 4) increases the flexibility of the quantum processor relative to a fixed quantum processor topology. Several different qubit configurations are achievable using single superconducting circuit 400, and increasingly diverse architectures become available by tiling a plurality of superconducting circuits, each of which can be differently programmed. This enables different types of problems, and relationships between problem variables, to be directly mapped to qubits within a quantum processor. As use of one or more superconducting circuits may require fewer and/or shorter chains to embed a topological representation, the quantum processor may beneficially be able to solve problems with a higher complexity that include a larger number of variables.

Each of multi-loop qubits 510, 520, 530, 540, 610, and 620 include two CJJs of set of flux qubit CJJs 404. However, a multi-loop superconducting qubit can optionally include only one flux qubit CJJ. For example, as can be seen in FIG. 3A, superconducting flux qubit 300 has two superconducting loops 304, 306 and includes one Josephson junction 302. For any of the qubits configured in superconducting circuit 400, one of the two flux qubit CJJs can be tuned to be in a functionally “OFF” state by maximizing its effective Josephson energy. As a result, no electron tunneling occurs through the flux qubit CJJ and this element behaves like an open circuit. In such implementations, only the flux qubit CJJ having a smaller Josephson energy is tuned to influence the behavior of the qubit during quantum computation.

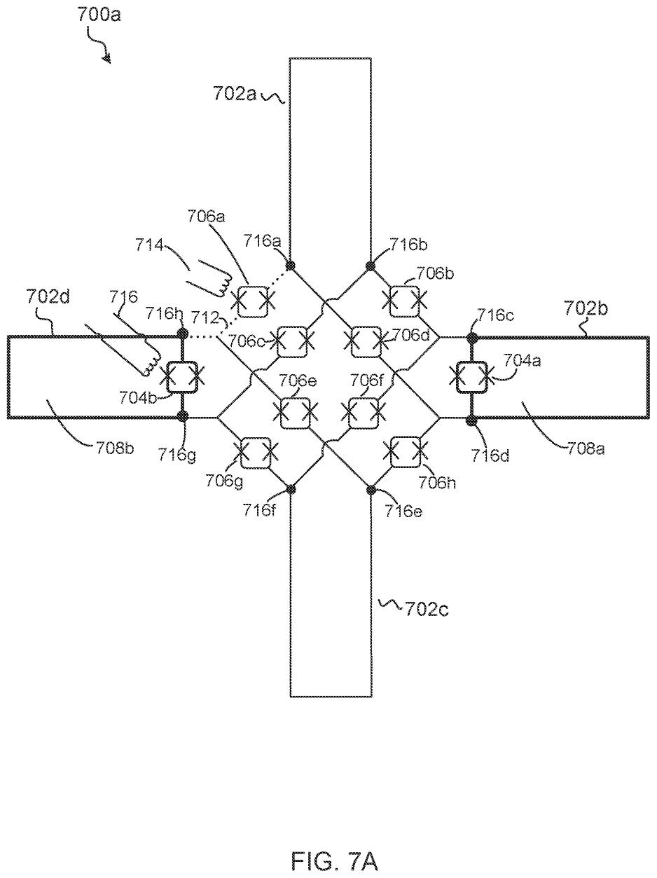

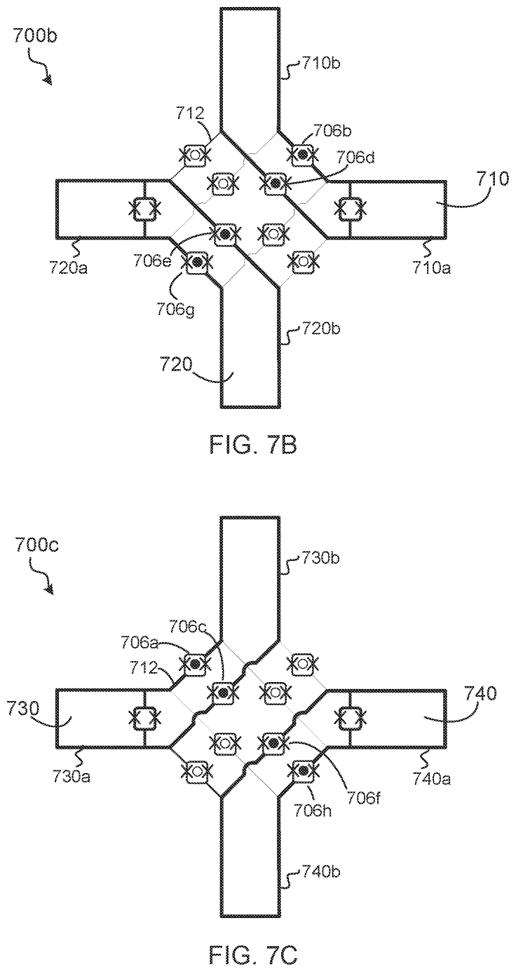

Alternatively, a superconducting circuit can be provided that that is similar to superconducting circuit 400, but only includes two flux qubit CJJs. FIGS. 7A-7C illustrate an example of such a superconducting circuit.

FIG. 7A is an alternative superconducting circuit to FIG. 4, in accordance with the present systems, devices, and methods. A superconducting circuit 700a can provide a set of superconductive arms (702a, 702b, 702c, and 702d, hereinafter also 702) that are that are connected to one another across a connection structure. The connection structure includes a set of superconductive arm connection lines (only superconductive arm connection line 712 is called out for visual clarity, and is shown as a dotted line) and a set of connecting CJJs (706a, 706b, 706c, 706d, 706e, 706f, 706g, 706h, hereinafter also collectively referred to as 706) that each interrupt a respective superconductive arm connection line 712. Selective tuning of at least some of the connecting CJJs of set of tunable connecting CJJs 706 can establish one or more closed superconductive paths that each form a respective qubit. Superconducting circuit 700a also includes a set of flux qubit CJJs (704a, 704b, hereinafter also 704).

Set of superconductive arms 702, set of connecting CJJs 706, and each of the individual CJJs of set of flux qubit CJJs 704 may have similar properties to superconductive arms 402, set of connecting CJJs 406, and each of the individual flux qubit CJJs of set of flux qubit CJJs 404 of superconducting circuit 400 (FIG. 4). However, unlike superconducting circuit 400, not every superconductive arm 702 includes a respective flux qubit CJJ 704. Though only one is shown, it is to be understood that superconducting circuit 700a includes a flux qubit CJJ interface 716 corresponding to each CJJ of set of flux qubit CJJs 704 and a connecting CJJ interface 714 corresponding to each CJJ of set of connecting CJJs 706, that respectively have the same or similar biasing functionality as flux qubit CJJ interface 410 (FIG. 4) and connecting CJJ interface 414 (FIG. 4).

Superconducting circuit 700a includes four superconductive arms: first superconductive arm702a, second superconductive arm 702b, third superconductive arm 702c, and fourth superconductive arm 702d. Each superconductive arm (702a, 702b, 702c, 702d) is a trace of superconducting material having an open shape that extends between two connection nodes. First superconductive arm 702a is a trace of superconducting material that extends between first connection node 716a and second connection node 716b by way of a U shape. Second superconductive arm 702b is a trace of superconducting material that extends between third and fourth connection nodes 716c, 716d. Third superconductive arm 702c is a trace of superconducting material that extends between fifth and sixth connection nodes 716e, 716f. Fourth superconductive arm 702d is a trace of superconducting material that extends between seventh and eighth connection nodes 716g, 716h.

The connection structure of superconducting circuit 700a can include set of superconductive arm connection lines 712, each which is interrupted by a respective CJJ of set of tunable connecting CJJs 706. Like each of superconductive arm connection lines 412 (FIG. 4), each of superconductive arm connection line 712 can extend between a connection node of one superconductive arm and a connection node of another superconductive arm. For example, called out superconductive arm connection line 712 extends between first connection node 716a of first superconductive arm 702a and eighth connection node 716h of fourth superconductive arm 702d.

Set of connecting CJJs 706 that interrupts set of superconductive arm connection lines 712 includes eight connecting CJJs (706a, 706b, 706c, 706d, 706e, 706f, 706g, 706h). In superconducting circuit 700a, each superconductive arm of set of superconductive arms 702 can optionally be in electrical communication with each CJJ of set of connecting CJJs 706, and superconducting paths can optionally be established between any ones of superconductive arms (702a, 702b, 702c, 702d) and CJJs of set of connecting CJJs 706.

As can be seen in FIG. 7A, set of flux qubit CJJs 704 includes only two flux qubit CJJs: a first flux qubit CJJ 704a electrically arranged between third and fourth connection nodes 716c, 716d of second superconductive arm 702b; and a second flux qubit CJJ 704b electrically arranged between seventh and eighth connection nodes 716g, 716h of fourth superconductive arm 702d.

Although FIG. 7A shows first and second flux qubit CJJs 704a and 704b as being physically and electrically connected to second and fourth superconductive arms 702b and 702d respectively, this is merely an example.

First and second flux qubit CJJs 704a and 704b can be electrically arranged between a pair of connection nodes corresponding to any two superconductive arms 702 in superconducting circuit 700a.

Like set of connecting CJJs 406 (FIG. 4), set of connecting CJJs 706 can be programmed to be in an “ON” state or an “OFF” state to selectively control current flow and establish closed superconductive paths (i.e., qubits) within superconducting circuit 700a. To configure a multi-loop qubit, set of connecting CJJs 706 can be tuned to provide a closed superconductive path between at least two superconductive arms 702, in which at least one superconductive arm of set of superconductive arms 702 is coupled to one CJJ of set of flux qubit CJJs 704.

In an implementation where all CJJs of set of connecting CJJs 706 are tuned to be in the “OFF” state, superconducting circuit 700a provides two uncoupled rf-SQUID qubits. For instance, in such an implementation, a first qubit 708a can have a closed superconductive path formed by second superconductive arm 702b in series with first flux qubit CJJ 704a and a second qubit 708b can have a closed superconductive path formed by fourth superconductive arm 702d in series with second flux qubit CJJ 704b. The superconducting paths of first qubit 708a and second qubit 708b are shown by bolded lines in FIG. 7A for example purposes.

FIGS. 7B and 7C illustrate the superconducting circuit of FIG. 7A programmed to provide two multi-loop qubits in two different configurations. FIGS. 7B and 7C illustrate superconducting circuit configurations 700b and 700c respectively, which are arrangements provided by selectively tuning the CJJs of set of connecting CJJs 706 of superconducting circuit 700a.

The orientations of superconductive arms of set of superconductive arms 702 and qubits configured on superconducting circuit 700a are described herein in a manner similarly to superconductive arms 402 and qubits configured on superconducting circuit 400 (FIG. 4), as described above, based on the arrangement of these elements on the planes of the pages of FIGS. 7A-7C.

Superconducting circuit configuration 700b of FIG. 7B is configured similarly to superconducting circuit configuration 500a of FIG. 5A by tuning set of connecting CJJs 706 in the same manner as set of connecting CJJs 406 (FIG. 4), differing in that superconducting circuit configuration 700b is programmed on superconducting circuit 700a instead of superconducting circuit 400. Therefore, superconducting circuit configuration 700b has a first qubit 710 oriented as a “right-up” qubit and a second qubit 720 oriented as a “left-down” qubit.

A closed superconductive path that forms first qubit 710 includes: a first superconducting first qubit loop 710a consisting of: second superconductive arms 702b and at least a portion of first flux qubit CJJ 704a, and a second superconducting first qubit loop 710b consisting of: first superconductive arm 702a, superconductive arm connection lines 712 interrupted by second and fourth connecting CJJs 706b, 706d, and at least a portion of first flux qubit CJJ 704a. First superconducting first qubit loop 710a and second superconducting first qubit loop 710b are electrically connected across first flux qubit CJJ 704a.

A closed superconductive path that forms second qubit 720 includes: a first superconducting second qubit loop 720a consisting of: fourth superconductive arm 702d and at least a portion of second flux qubit CJJ 704b, and a second superconducting second qubit loop 720b consisting of: third superconductive arm 702c, superconductive arm connection lines 712 interrupted by fifth and seventh connecting CJJs 706e, 706g, and at least a portion of second flux qubit CJJ 704b. First superconducting second qubit loop 720a and second superconducting second qubit loop 720b are electrically connected across second flux qubit CJJ 704b.

Superconducting circuit configuration 700c of FIG. 7C is configured similarly to superconducting circuit configuration 500b of FIG. 5B by tuning set of connecting CJJs 706 in the same manner as set of connecting CJJs 406, differing in that superconducting circuit configuration 700c is programmed on superconducting circuit 700a instead of superconducting circuit 400 (FIG. 4). Therefore, superconducting circuit configuration 700c has a first qubit 730 oriented as a “left-up” qubit and a second qubit 740 oriented as a “right-down” qubit.

A closed superconductive path that forms first qubit 730 includes: a first superconducting first qubit loop 730a consisting of: fourth superconductive arm 702d and at least a portion of second flux qubit CJJ 704b, and a second superconducting first qubit loop 730b consisting of: first superconductive arm 702a, superconductive arm connection lines 712 interrupted by first and third connecting CJJs 706a, 706c, and at least a portion of second flux qubit CJJ 704b. First superconducting first qubit loop 730a and second superconducting first qubit loop 730b are electrically connected across second flux qubit CJJ 704b.

A closed superconductive path that forms second qubit 740 includes: a first superconducting second qubit loop 740a consisting of: second superconductive arm 702b and a portion of first flux qubit CJJ 704a, and a second superconducting second qubit loop 740b consisting of: third superconductive arm 702c, superconductive arm connection lines 712 interrupted by sixth and eighth connecting CJJs 706f, 706h, and at least a portion of first flux qubit CJJ 704a. First superconducting second qubit loop 740a and second superconducting second qubit loop 740b are electrically connected across first flux qubit CJJ 704a.

Despite removing two flux qubit CJJs from the circuit of superconducting circuit 400 (e.g., flux qubit CJJs at the locations of first flux qubit CJJ 404a electrically arranged between first and second connection nodes 416a, 416b of first superconductive arm 402a and third flux qubit CJJ 404c electrically arranged between fifth and sixth connection nodes 416e, 416f of third superconductive arm 402c, FIG. 4), the configurations of qubits 510, 520, 530, and 540 each having one of its respective flux qubit CJJs turned off can be realized as qubits 710, 720, 730, and 740. Superconducting circuit 700a can be programmed to provide the same “right-down” and “left-up” qubits or “right-up” and “left-down” qubits as superconducting circuit 400, but requires fewer circuit components. Two less flux qubit CJJs, and consequently less circuitry to tune two flux qubit CJJs (e.g., two of flux qubit CJJ interface 410), may advantageously reduce a footprint of the circuit, associated cost, and number of signal paths travelling to the circuit that can be exposed to environmental noise and radiation.

However, due to the reduced number of flux qubit CJJs, superconducting circuit 700a is limited in its possible configurations relative to superconducting circuit 400 (FIG. 4).

For example, superconducting circuit 400 (FIG. 4) can be programmed to configure horizontal and vertical oriented multi-loop qubits, such as horizontal qubit 610 of FIG. 6A and vertical qubit 620 of FIG. 6B. With the two flux qubit CJJs 704a, 704b arranged as shown in FIG. 7A, superconducting circuit 700a cannot be configured to provide a vertical qubit. In the plane of the pages of FIGS. 7A-7C, a vertical qubit would consist of a superconductive path including first and third superconductive arms 702a and 702c. The superconducting path would be interrupted by at least one flux qubit CJJ of set of flux qubit CJJs 704 to form two or more superconductive qubit loops. Since neither vertically oriented superconductive arm (702a, 702c) is coupled to a flux qubit CJJ, a vertical qubit cannot be realized.

Although a vertical qubit cannot be configured on superconducting circuit 700a as depicted in FIG. 7A, it is to be understood that alternative implementations of superconducting circuit 700a may have flux qubit CJJs connected to the vertically oriented superconductive arms (702a, 702c). In such an implementation, a horizontal qubit would not be configurable.

Though superconducting circuit 700a does not provide all of the possible configurations made available by superconducting circuit 400 (FIG. 4), the programmable nature of superconducting circuit 700a has several of the same above-described advantages. Even if superconducting circuit 700a were to be limited to superconducting circuit configurations 700b and 700c of FIGS. 7B and 7C, up to 2^{N/2} possible architectures are obtainable, where N is a number of CJJs in set of flux qubit CJJs 704. The configurable architecture of superconducting circuit 700a provides significant flexibility to embedding a problem onto an analog processor via a mapping of variables to qubits.

In superconducting circuits 400 and 700a, sets of connecting CJJs 406 and 706 each include eight connecting CJJs and a same connection wiring between their respective four superconductive arms 402 and 702. However, this is only one example. In some implementations, a superconducting circuit can optionally include more than four superconductive arms or less than four superconductive arms.

In some implementations, superconductive arms of a superconducting circuit can be coupled by wiring having a different arrangement than that shown in FIGS. 4, 5A, 5B, 6A, 6B, 7A, 7B, and 7C. In some implementations, a set of connecting CJJs can include more or less than eight connecting CJJs. The implementations provided herein are not intended to be limiting, and a programmable superconducting circuit can have any suitable number and arrangement of elements for configuring one or more qubit structures.

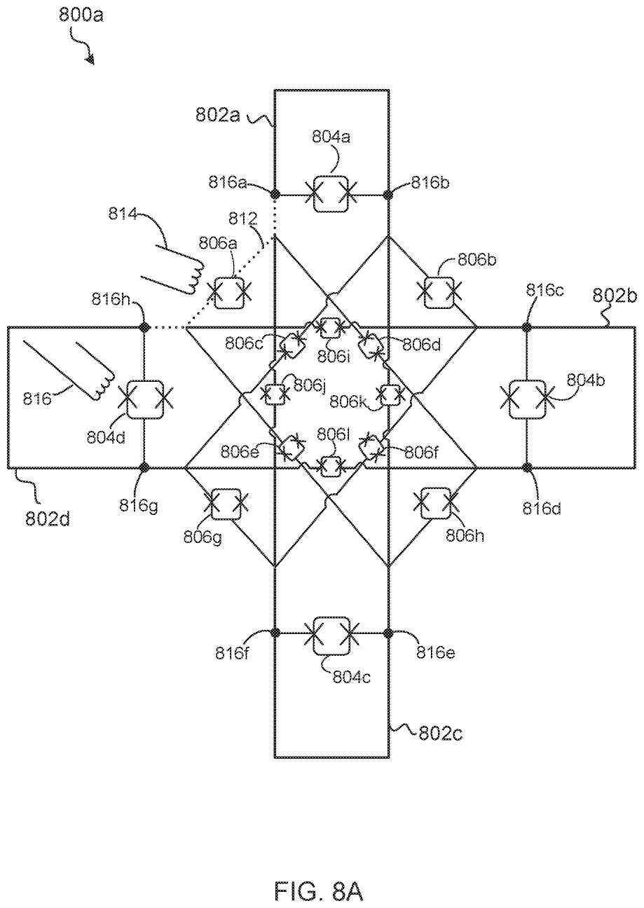

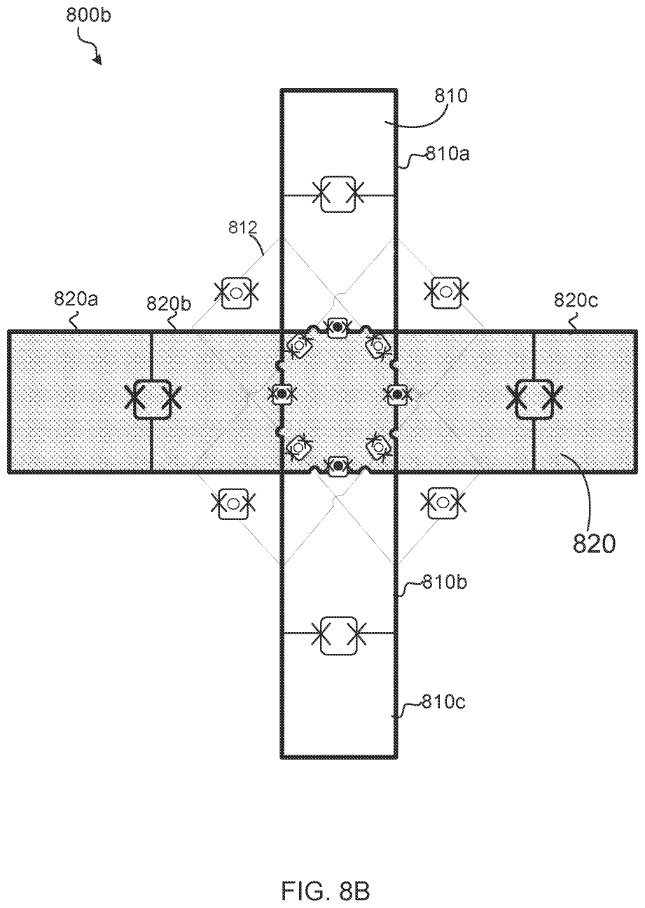

One such example of a superconducting circuit having a different connection structure that includes a different number of superconductive arm connection lines and connecting CJJs for coupling superconductive arms is shown in FIG. 8A.

FIG. 8A illustrates another alternative superconducting circuit to FIG. 4, in accordance with the present systems, devices, and methods. A superconducting circuit 800a can provide a structure with a set of superconductive arms (802a, 802b, 802c, and 802d, hereinafter also 802) that are communicatively coupled by a connection structure that includes a set of superconducting arm connection lines 812 (only one called out) and a set of connecting CJJs (806a, 806b, 806c, 806d, 806e, 806f, 806g, 806i, 806j, 806k, 8061, hereinafter also collectively referenced as 806). Selective tuning of at least some of the CJJs of set of connecting CJJs 806 can establish one or more closed superconducting paths that provide one or more multi-loop qubits. Superconducting circuit 800a also includes a set of flux qubit CJJs (804a, 804b, 804c, 804d, hereinafter also 804).

Superconductive arms 802, set of flux qubit CJJs 804, and individual superconductive arm connection lines 812 and connecting CJJs of set of connecting CJJs 806 may have similar properties to superconductive arms 402, set of flux qubit CJJs 404, and individual superconductive arm connection lines 412 and CJJs of set of connecting CJJs 406, respectively, of superconducting circuit 400. Though only one is shown, it is to be understood that superconducting circuit 800a includes a flux qubit CJJ interface 816 corresponding to each CJJ of set of flux qubit CJJs 804 and a connecting CJJ interface 814 corresponding to each CJJ of set of connecting CJJs 806, that respectively have the same biasing functionality as flux qubit CJJ interface 410 and connecting CJJ interface 414.

Superconducting circuit 800a includes four superconductive arms: first superconductive arm 802a, second superconductive arm 802b, third superconductive arm 802c, and fourth superconductive arm 802d, each comprising an open shape of superconducting material that extends between a pair of connection nodes. First flux qubit CJJ 804a is electrically arranged between a first and a second connection node 816a, 816b of first superconductive arm 802a. Second flux qubit CJJ 804b is electrically arranged between a third and a fourth connection node 816c, 816d of second superconductive arm 802b. Third flux qubit CJJ 804c is electrically arranged between a fifth and a sixth connection node 816e, 816f of third superconductive arm 802c. Fourth flux qubit CJJ 804d is electrically arranged between a seventh and an eighth connection node 816e, 816f of fourth superconductive arm 802d.

Each superconductive arm of set of superconductive arms 802 are coupled to one another via the connection structure that includes set of superconductive arm connection lines 812 interrupted by set of connecting CJJs 806., Each connection node of each superconductive arm (802a, 802b, 802c, 802d) is connected to at least one connection node of at least one other superconductive arm (802a, 802b, 802c, 802d) via one of more superconductive arm connection line 812.

However, unlike superconducting circuit 400, set of connecting CJJs 806 includes twelve connecting CJJs (806a, 806b, 806c, 806d, 806e, 806f, 806g, 806h, 806i, 806j, 806k, 8061) instead of eight. Subsequently, superconducting circuit 800a includes twelve corresponding superconductive arm connection lines 812 that extend between connection nodes of superconductive arms through which connecting CJJs of set of connecting CJJs 806 control a flow of current.

It is to be understood that the specific arrangement of set of connecting CJJs 806 shown in FIGS. 8A and 8B is merely an example. Set of superconductive arm connection lines 812 interrupted by set of connecting CJJs 806 is arranged differently than in superconducting circuit 400. Subsequently, superconductive arms 802 can be connected to one another in additional and alternative arrangements that might not be available when configuring superconducting circuit 400 (FIG. 4).

For instance, superconducting circuit 800a can be programmed to have a configuration including both a vertically oriented multi-loop qubit and a horizontally oriented multi-loop qubit.

The orientations of superconductive arms 802 and qubits configured on superconducting circuit 800a are described herein in a manner similarly to superconductive arms 402 and qubits configured on superconducting circuit 400 (FIG. 4), as described above, based on the arrangement of these elements on the planes of the pages of FIGS. 8A-8B.

FIG. 8B illustrates the superconducting circuit of FIG. 8A, programmed to provide two multi-loop qubits in one configuration. Here, a superconducting circuit configuration 800b illustrates an example arrangement of a horizontally oriented multi-loop qubit and vertically oriented multi-loop qubit provided by selectively tuning the CJJs of set of connecting CJJs 806 of superconducting circuit 800a.

Superconducting circuit configuration 800b includes two multi-loop superconducting qubits: a first qubit 810 and a second qubit 820. First qubit 810 is a “vertical” qubit and second qubit 820 is a “horizontal” qubit. In FIG. 8B, second qubit 820 is filled with a repeating pattern for visual clarity.

To program superconducting circuit 800a to obtain superconducting circuit configuration 800b, the following connecting CJJs are tuned to the “ON” state: ninth connecting CJJ 806i, tenth connecting CJJ 806j, eleventh connecting CJJ 806k, and twelfth connecting CJJ 8061. The remaining connecting CJJs (806a, 806b, 806c, 806d, 806e, 806f, 806g, 806h) are tuned to the “OFF” state.

First qubit 810 is formed by a closed superconductive path that includes: first superconductive arm 802a, third superconductive arm 802c, superconductive arm connection line 812 interrupted by tenth connecting CJJ 806j that extends between first connection node 816a of first superconductive arm 802a and sixth connection point or node 816f of third superconductive arm 802c, and superconductive arm connection line 812 interrupted by eleventh connecting CJJ 806k that extends between second connection node 816b of first superconductive arm 802a and fifth connection point or node 816e of third superconductive arm 802c.

Likewise, second qubit 820 is formed by a closed superconductive path that includes: second superconductive arm 802b, fourth superconductive arm 802d, superconductive arm connection line 812 interrupted by ninth connecting CJJ 806i that extends between third connection node 816c of second superconductive arm 802b and eighth connection point or node 816h of fourth superconductive arm 802d, and superconductive arm connection line 812 interrupted by twelfth connecting CJJ 8061 that extends between fourth connection node 816d of second superconductive arm 802b and seventh connection point or node 816g of fourth superconductive arm 802d. The closed superconductive paths of first qubit 810 and second qubit 820 are shown by bolded lines in FIG. 8B for visual clarity.

First qubit 810 includes: a first superconducting first qubit loop 810a consisting of: first superconductive arm 802a and at least a portion of first flux qubit CJJ 804a; a second superconducting first qubit loop 810b consisting of:

superconductive arm connection lines 812 that are interrupted by “ON” tenth and eleventh connecting CJJs (806j, 806k), and at least a portion of each of first and third flux qubit CJJs 804a, 804c; and third superconducting first qubit loop 810c consisting of: third superconductive arm 802c and at least a portion of third flux qubit CJJ 804c. First superconducting first qubit loop 810a and second superconducting first qubit loop 810b are electrically connected across first flux qubit CJJ 804a. Second superconducting first qubit loop 810b and third superconducting first qubit loop 810c are electrically connected across third flux qubit CJJ 804c.

Second qubit 820 includes: a first superconducting second qubit loop 820a consisting of: fourth superconductive arm 802d and at least a portion of fourth flux qubit CJJ 804d; a second superconducting second qubit loop 820b consisting of: superconductive arm connection lines 812 that are interrupted by “ON” ninth and twelfth connecting CJJs (806i, 8061), and at least a portion of each of fourth and second flux qubit CJJs 804d, 804b; and third superconducting second qubit loop 820c consisting of: second superconductive arm 802b and at least a portion of second flux qubit CJJ 804b. First superconducting second qubit loop 820a and second superconducting second qubit loop 820b are electrically connected across fourth flux qubit CJJ 804d. Second superconducting second qubit loop 820b and third superconducting second qubit loop 820c are electrically connected across second flux qubit CJJ 804b.

The four “ON” connecting CJJs (806i, 806j, 806k, 8061) of superconducting circuit configuration 800b are CJJs with no equivalently arranged tunable connectors in superconducting circuits 400 and 700a. As such, the arrangement of qubits 810 and 820 cannot be realized by superconducting circuits having fewer connecting CJJs and/or having no superconductive arm connection wires interrupted by connecting CJJs that are each collinear with points of two superconductive arms.

Superconducting circuit 800a can also be programmed to provide other qubit configurations that may not be available by programming superconducting circuits 400 (FIGS. 4) and 700a (FIG. 7A). In other implementations, different subsets of CJJs of set of connecting CJJs 806 may be set to the “ON” state to provide alternative qubit configurations of superconducting circuit 800a. Some or all of the connecting CJJs in the “OFF” state (806a, 806b, 806c, 806d, 806e, 806f, 806g, 806h) in superconducting circuit configuration 800b may be set to the “ON” state to configure one or more of qubits having “left-down”, “right-up”, “left-up”, and “right-down” orientations.

Though all elements connecting superconductive arms 402, 702, 802 of superconducting circuits 400 (FIGS. 4), 700a (FIGS. 7A), 800a (FIG. 8A) have been described as CJJs of respective sets of connecting CJJs 406, 706, 806, this is only an example and is not intended to be limiting. One or more CJJs of set of connecting CJJs 406, 706, 806 can optionally be replaced with a different tunable connector that can be selectively tuned to an “OFF” or “ON” state to configure a closed superconductive path.

In some implementations, the different tunable connector can advantageously provide a bigger ratio between an inductance value of a tunable connector in the “ON” state and an inductance value of a tunable connector in the “OFF” state. For instance, a ratio having an infinite value provides perfectly uncoupled qubits configured on superconducting circuits 400 (FIGS. 4), 700a (FIGS. 7A), 800a (FIG. 8A).

One example of a different tunable connector can be an array of DC-SQUIDs.

Another example of a different tunable connector can be the tunable super-inductor circuit described in Bell et al. (M. T. Bell et. al., Quantum Superinductor with Tunable Non-Linearity, https://arxiv.org/pdf/1206.0307.pdf). This tunable super-inductor circuit has a ladder structure including coupled unit cells. Each unit cell consists of an asymmetric dc-SQUID with a single “small” junction in a first arm and three “large” Josephson junctions in a second arm, and adjacent unit cells are coupled by one large Josephson junction. This tunable super-inductor circuit may provide high-impedance isolation based on Bloch oscillations and may limit exposure of the qubits to flux and charge noises.

As described above with respect to sets of connecting CJJs 406 and 706, one or more CJJs of set of connecting CJJs 806 that are tuned to an “ON” state can optionally function as one or more L-tuners. The “ON” CJJs of set of connecting CJJs 806 can compensate for discrepancies in qubit inductance of each qubit, or a set of qubits, configured on superconducting circuit 800a. This may reduce a number of additional L-tuners required, or eliminate the need for additional L-tuners, within an analog processor.

As described above with respect to qubits architectures or topologies configured using superconducting circuit 400, any one or more multi-loop superconducting qubits on superconducting circuit 800a can be configured such that one of its flux qubit CJJs can be tuned to a functionally “OFF” state by maximizing its effective Josephson energy.

Likewise, there can be an alternative superconducting circuit having a same number of connecting CJJs as in set of connecting CJJs 806, but only two flux qubit CJJs. This may provide an arrangement with a similar relationship to superconducting circuit 800a as found between superconducting circuit 400 (FIG. 4) and superconducting circuit 700a (FIG. 7A). This alternative superconducting circuit would provide a different number and type of qubit configurations as compared to superconducting circuits 800a and 700a.

Like superconducting circuit 400 (FIG. 4), superconducting circuit 700a (FIG. 7A) and superconducting circuit 800a (FIG. 8A) can also be all or a portion of a superconducting quantum processor. A configurable superconducting quantum processor can include a repeating lattice structure of the circuit of superconducting circuit 700a or superconducting circuit 800a, and the tiled superconducting circuits can be configured to provide a desired topology. In other implementations, configurable superconducting quantum processor can include a repeating lattice structure of other like superconducting circuits having other numbers of CJJs in its set of flux qubit CJJs and/or other numbers of CJJs in its set of connecting CJJs.

In some implementations, a configurable superconducting quantum processor may have a lattice structure of non-uniform superconducting circuits, such as more than one selected from: superconducting circuit 400 (FIG. 4), superconducting circuit 700a (FIG. 7A), superconducting circuit 800a (FIG. 8A), and other like superconducting circuits having other numbers of CJJs in its set of flux qubit CJJs and/or other numbers of CJJs in its set of connecting CJJs.

In some implementations, as each superconducting qubit comprises at least one CJJ of set of flux qubit CJJs 404, 704, 804, a maximum number of superconducting qubits that can be configured on one of superconducting circuits 400, 700a, 800a, or another superconducting circuit described herein corresponds to a number of CJJs in set of flux qubit CJJs 404, 704, 804.

In some implementations, architecture of superconducting qubits configured on one of superconducting circuits 400, 700a, 800a, or another superconducting circuit described herein is reconfigurable to change a first arrangement of qubits thereon to a second arrangement of qubits that better map problem variables onto a quantum processor. In particular, the architecture of superconducting qubits can advantageously be reconfigured one or more times after manufacture of the superconductive integrated circuit, for example during use by an end user. A bias signal can be applied to CJJs of set of connecting CJJs 406, 706, 806 via connecting CJJ interfaces 414, 714, 814 to tune an associated inductance to selectively modify paths through which current flows between connection nodes of set of superconductive arms 402, 702, 802, thereby redefining the shapes and number of superconducting qubits.

Configurable superconducting circuits 400 (FIGS. 4), 700a (FIG. 7A), and 800a (FIG. 8A), as well as other like superconducting circuits forming at least a portion of a quantum processor, are advantageous in embedding a problem onto the quantum processor from a topological representation. Based on a known problem, one or more superconducting circuits can be configured to provide a qubit arrangement best suited for expressing relationships between the problem variables. Selectively programming a qubit configuration eases the embedding process, as fewer physical qubits, and consequently fewer chains, may be needed to represent the logical qubits of the topological representation. Embedding a problem using fewer and/or shorter chains may result in the ability to solve more complex problems using the quantum processor and better performance of the quantum processor during quantum computation.

### Coupling Compensation of Qubits on the Configurable Superconducting Circuit

Herein, it has been described that CJJs in sets of connecting CJJs 406, 706, 806 can be tuned to an “OFF” state, which inhibits current flow across respective superconductive arm connection lines 412, 712, 812 to selected superconductive arms 402, 702, 802. However, in a physical system, a small amount of current may still be transmitted between qubits across these paths, particularly when there is an insufficient ratio between inductance values of connecting CJJs in the “OFF” state and connecting CJJs in the “ON” state. As a result, there may be residual coupling between qubits configured using superconducting circuits 400 (FIGS. 4), 700a (FIG. 7A), or 800a (FIG. 8A). In some implementations, this undesirable residual coupling can be compensated for using tunable couplers.

Alternatively, undesirable residual coupling between qubits configured using superconducting circuits 400, 700a, or 800a can be compensated by leveraging the tunable nature of the connecting CJJs. To achieve this, two qubits configured on one of superconducting circuits 400, 700a, or 800a can be magnetically coupled in a manner that is fixed, cannot be tuned, and produces a persistent magnetic field. In some implementations, the persistent magnetic coupling can be established by a permanent magnet.

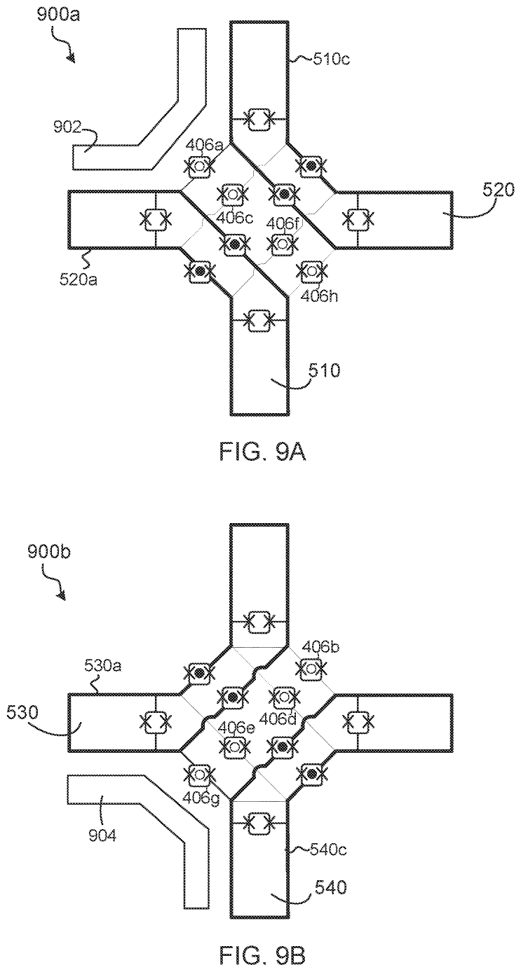

FIG. 9A illustrates coupling of the two multi-loop qubits as configured in FIG. 5A. A superconducting circuit configuration 900a includes superconducting circuit 400 programmed to include first qubit 510 and second qubit 520, oriented as a “right-up” and “left-down” multi-loop qubits, respectively. Superconducting circuit configuration 900a also includes a coupling superconducting loop 902 to provide magnetic coupling between first qubit 510 and second qubit 520, and in particular, between third superconducting first qubit loop 510c and first superconducting second qubit loop 520a.

In superconducting circuit configuration 900a, first, third, sixth, and eighth connecting CJJs 406a, 406c, 406f, 406h are tuned to the “OFF” state. Although the “OFF” state limits or substantially prevents current from flowing across these connecting CJJs 406a, 406c, 406f, 406h and their respective superconductive arm connection lines 412 (FIG. 4), a small amount of current may still flow between first qubit 510 and second qubit 520.

Residual coupling between first qubit 510 and second qubit 520 via one or more of superconductive arm connection lines 412 interrupted by first, third, sixth, and eighth connecting CJJs 406a, 406c, 406f, 406h can be a coupling in a first direction having a first sign. To counter-act this undesired residual coupling, coupling superconducting loop 902 provides a fixed, persistent magnetic coupling between first qubit 510 and second qubit 520 in a second direction that is substantially opposite to the first direction.

In some implementations, the residual coupling can be significantly reduced if the coupling strength of the fixed, persistent magnetic coupling has a same magnitude as the undesired residual coupling strength. To achieve this, one or more of CJJs of set of connecting CJJs 406 (FIG. 4) in the “OFF” state can be tuned to match the magnitude of the fixed, persistent magnetic coupling.

In superconducting circuit configuration 900a, bias signals can be provided to connecting CJJs in the “OFF” state (406a, 406c, 406f, 406h) to have an equal magnitude and opposite direction to the coupling of coupling superconducting loop 902. In some implementations, the bias signals can be transmitted to each CJJ via a respective connecting CJJ interface 414 (FIG. 4) as magnetic flux. In alternative implementations, the bias signals can be transmitted to each CJJ via an analog line to modify a critical current value of a respective connecting CJJ. The bias signal can be generated via a DAC, such as the one of one or more DACs used to set the states of set of connecting CJJs 406 (FIG. 4) to configure superconducting circuit configuration 900a. Performing coupling compensation using the same one or more DACs that configure first and second qubits 510 and 520 beneficially reduces an amount or circuitry and/or a number of devices required for programming superconducting circuit 400 (FIG. 4).

In some implementations, superconducting circuit configuration 900a can be a portion of the architecture of quantum processor 126 of computing system 100 (FIG. 1). Here, one or more DACs used to configure superconducting circuit 400 (FIG. 4) can be part of qubit control system 130 and/or coupler control system 132 in quantum computer 104. System memory 122 may include instructions or modules 124, that when executed by digital processor 106, cause coupler control system 132 to generate bias signals for transmission to CJJs of set of connecting CJJs 406 that counteract the fixed, persistent magnetic coupling between first and second qubits 510 and 520 produced by coupling superconducting loop 902.

Although not shown in FIG. 9A, a coupling superconducting loop can additionally or alternatively be arranged to couple other combinations of superconducting first qubit loops 510a, 510b, 510c to superconducting second qubit loops 520a, 520b, 520c. This may achieve a fixed, persistent magnetic coupling of first qubit 510 and second qubit 520 similar to that provided by coupling superconducting loop 902.

In some implementations, it may be advantageous to couple qubits 510, 520 using two coupling superconducting loops that are oriented differently from one another in applications where symmetry is desired in the architecture of an analog processor. In some implementations, coupling between first and second qubits 510 and 520 can be provided in both first and second coupling directions having first and second signs. This can be achieved through the addition of connecting CJJs in set of connecting CJJs 406 and/or through changing the shape of superconductive arms 402 by physical twisting of the superconducting wiring material or introducing a cross-back (e.g., “Figure-8” shape or infinity symbol shape in one or more layers of a fabrication, substrate, or a printed circuit board).

FIG. 9B illustrates coupling of the two multi-loop qubits as configured in FIG. 5B. A superconducting circuit configuration 900b is implemented via superconducting circuit 400 (FIG. 4) programmed to include first qubit 530 and second qubit 540, oriented as a “left-up” and “right-down” multi-loop qubits, respectively. Superconducting circuit configuration 900b also includes a coupling superconducting loop 904 to provide magnetic coupling between first qubit 530 and second qubit 540, and in particular, between first superconducting first qubit loop 530a and third superconducting second qubit loop 540c.

At least a majority of undesired residual coupling between first qubit 530 and second qubit 540 can be eliminated by providing bias signals to one or more of connecting CJJs in the “OFF” state (406b, 406d, 406e, 406g) to adjust a coupling between first and second qubits 530, 540 to have a same amplitude and different sign than the fixed, persistent magnetic coupling provided by coupling superconducting loop 904.

Superconducting circuit configuration 900b as shown in FIG. 9B shows how coupling compensation can be achieved between first and second qubits 530, 540. Coupling provided by coupling superconducting loop 904 is merely an example, and can optionally be provided by one or more coupling superconducting loops in the alternative arrangements previously described with respect to superconducting circuit configuration 900a.

Although superconducting circuit configurations 900a, 900b illustrate coupling compensation between qubits programmed onto superconducting circuit 400, a similar approach can be applied to qubits configured on superconducting circuits 700a, 800a, or any other superconducting circuit described herein.

CJJs of set of connecting CJJs 406 (FIG. 4) in superconducting circuit configurations 900a, 900b are operable to serve one of a multitude of functions in superconducting circuit 400. CJJs of set of connecting CJJs 406 tuned to an “ON” state can determine a superconducting path, and therefore a resulting qubit configuration. One or more of the “ON” CJJs of set of connecting CJJs 406 can be used as L-tuners to adjust for inductance discrepancies in qubits to which they belong. The tunability of CJJs of set of connecting CJJs 406 (FIG. 4) that are not part of qubits provide a mechanism for performing coupling compensation.

As such, the potential uses of CJJs of set of connecting CJJs 406 (FIG. 4) may reduce the need for additional on-chip devices and/or circuitry for qubit and coupler biasing. The described schemes may limit a footprint and cost of a superconducting circuit. A number of interconnects between on-chip and external devices, and on-chip and external devices, can be reduced, thereby limiting exposure of the qubits to flux noise, charge noise, and blackbody radiation. A number of control signals sent to superconducting circuit 400 may also be reduced relative to a non-programmable circuit having qubits and couplers. The noted advantages of superconducting circuit configurations described herein may be amplified when scaled to an analog processor consisting of a lattice of the described superconducting circuits.

### Methods of Configuring Qubits in a Programmable Superconducting Circuit

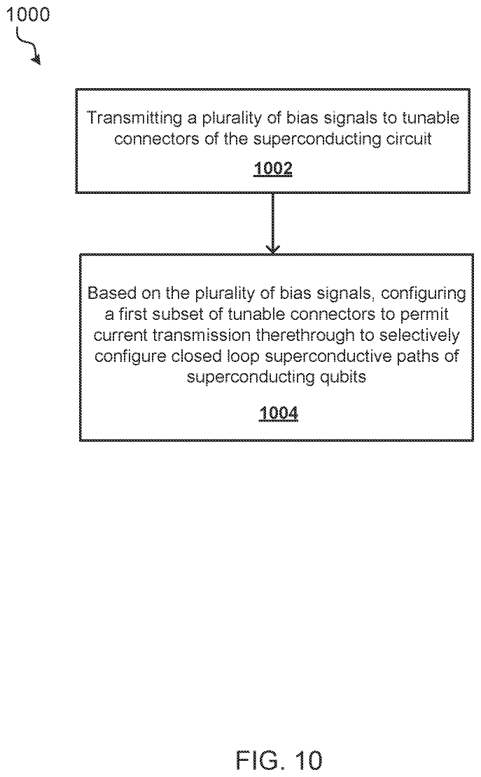

FIG. 10 is a flow diagram of a method 1000 to program a superconducting circuit to configure one or more superconducting qubits, in accordance with the present systems, devices, and methods.

Using method 1000, one or more superconducting qubits can be configured on a superconducting circuit, such as superconducting circuit 400 (FIGS. 4), 700a (FIGS. 7A), 800a (FIG. 8A), or another superconducting circuit described herein. Programming a superconducting circuit using method 1000 may result in any one of superconducting circuit configurations 500a, 500b, 600a, 600b, 700b, 700c, 800b, or any other superconducting circuit configuration described herein.

In some implementations, method 1000 is performed by at least one digital processor in communication with at least one analog processor. To perform method 1000, the digital processor may provide control signals or instructions to the analog processor, directly or indirectly, to perform programming thereof.

In at least some implementations, method 1000 can be executed on a hybrid computing system comprising at least one analog processor and a digital computer with at least one digital processor, such as computing system 100 including digital computer 102, digital processor 106, and quantum computer 104, quantum processor 126, or the quantum processor consisting of circuit 200. In some implementations, digital processor 106 may execute instructions stored in system memory 122 for interfacing with quantum computer 104. The execution of such instruction may cause digital processor 106 to transmit control signals via controller 118 to qubit control system 130 of quantum computer 104. Based on these control signals, qubit control system 130 may generate bias flux signals that are applied to qubits in the quantum processor.

In other implementations, method 1000 can be executed in an alternative manner in which control signals can be provided directly to the superconducting circuit to configure the one or more superconducting qubits.

In implementations where a portion of the analog processor is provided by circuit 200 (FIG. 2), these bias flux signals can be transmitted to CJJs 231, 232 of qubits 201, 202 via inductive interfaces 221, 224. Here, qubits 201, 202 can be qubits configured as part of any of superconducting circuits 400, 700a, and 800a and/or superconducting circuit configurations 500a, 500b, 600a, 600b, 700b, 700c, and 800b.

The superconducting circuit includes: a set of superconductive arms, each comprised of a trace of superconductive material having an open shape that extends between a respective first and second connection node; a set of Josephson junctions, each of which is electrically arranged between the first and the second connection node of a same superconductive arm; a set of superconductive arm connection lines, each extending between one of a first and a second connection node of a superconductive arm and one of a first and a second connection node of a different superconductive arm; and, a set of tunable connecting elements, each which interrupts a respective superconductive arm connection line.

In some implementations, the superconducting circuit can be one or superconducting circuits 400 (FIGS. 4), 700a (FIG. 7A), or 800a (FIG. 8A), and the set of superconductive arms can be one of set of superconductive arms 402a, 402b, 402c, 402d, 702a, 702b, 702c, 702d, or 802a, 802b, 802c, 802d. The set of Josephson junctions can be one of set of flux qubit CJJs 404a, 404b, 404c, 404d, 704a, 704b, or 804a, 804b, 804c, 804d. In some implementations, the set of tunable connectors can be one of set of connecting CJJs 406a, 406b, 406c, 406d, 406e, 406f, 406g, 406h, 706a, 706b, 706c, 706d, 706e, 706f, 706g, 706h, or 806a, 806b, 806c, 806d, 806e, 806f, 806g, 806h; alternatively, some or all tunable connectors of the set of tunable connectors can be DC-SQUID arrays or tunable super-inductors.

Method 1000 comprises acts 1002 and 1004; however, a person skilled in the art will understand that the number of acts illustrated is an example, and, in some implementations, certain acts may be omitted, further acts may be added, and/or the order of the acts may be changed.

At 1002, a digital computer causes a plurality of bias signals to be transmitted or otherwise provided to the superconducting circuit. Each bias signal of the plurality of bias signals can be transmitted to a respective tunable connector of a set of tunable connectors.

In some implementations, bias signals can be transmitted to: CJJs of set of connecting CJJs 406 of superconducting circuit 400 via connecting CJJ interfaces 414; CJJs of set of connecting CJJs 706 of superconducting circuit 700a via connecting CJJ interfaces 714; or CJJs of set of connecting CJJs 806 of superconducting circuit 800a via connecting CJJ interfaces 814.

In some implementations, transmitting or otherwise providing the plurality of bias signals to the superconducting circuit may include inputting a desired qubit configuration to a digital computer or selecting a desired qubit configuration to the digital computer, and instructing an analog computer to perform configuration of the one or more superconducting qubits by transmitting one or more control signals. This may further include: receiving the one or more control signals via DACs of the analog computer; using the DACs to generate the plurality of bias signals; and transmitting the bias signals to the tunable connectors via bias interfaces. In some implementations, bias interfaces can be analog lines, inductive interfaces, or any other suitable bias interfaces.

At 1004, a first subset of tunable connectors of the tunable connectors are configured to permit current transmission through the first subset of tunable connectors and across the superconductive arm lines that they interrupt. The first subset of tunable connectors is determined based on the plurality of bias signals received by the tunable connectors. An arrangement of the first subset of tunable connectors selectively electrically couples superconductive arms of the set of superconductive arms to configure a closed superconductive path of each qubit of the one or more superconducting qubits. Each closed superconductive path includes at least: at least one superconductive arm of the set of superconductive arms and at least a portion of at least one CJJ of the set of CJJs.

For instance, in some implementations, first connecting CJJ 406a of superconducting circuit 400 may be part of the first subset of tunable connectors. A transmitted control signal from a digital computer, such as digital computer 102 of computing system 100, results in a generated bias signal. The generated bias signal may be transmitted to connecting CJJ interface 414. In FIG. 4, where connecting CJJ interface 414 is an inductive interface, the bias signal may be transmitted to first connecting CJJ 406a in terms of flux quanta. A decrease in flux value of first connecting CJJ 406a results in a decrease of a corresponding Josephson inductance, thereby setting first connecting CJJ 406a to an “ON” state and permitting current transmission across first connecting CJJ 406a.

In an alternative implementation, first connecting CJJ 406a may not be part of the first subset of tunable connectors. A bias signal transmitted to first connecting CJJ 406a via connecting CJJ interface 414 may increase a flux value of first connecting CJJ 406a, increase a resultant Josephson inductance, and prevent current transmission across first connecting CJJ 406a and a respective superconductive arm connection line 412 that it interrupts.

A first subset of the bias signals may configure the first subset of tunable connectors to be set to an “ON” state. Conversely, a second subset of bias signals may configure a second subset of tunable connectors to be in an “OFF” state, which may inhibit current transmission through the second subset of tunable connectors.

For example, for applying method 1000 to program superconducting circuit 400 to have superconducting circuit configuration 500b, bias signals can be applied to each CJJ of set of connecting CJJs 406. The first subset of tunable connectors can include: first connecting CJJ 406a, third connecting CJJ 406c, sixth connecting CJJ 406f, and eighth connecting CJJ 406h. A first subset of bias signals can be applied to the first subset of connecting CJJs to set them to the “ON” state, allowing current to be transmitted across superconductive arm connection lines 412 that are interrupted by the first subset of connecting CJJs. In contrast, the second subset of tunable connectors (including second, fourth, fifth, and seventh connecting CJJs 406b, 406d, 406e, and 406g), can be set to the “OFF” state.

In some implementations, the first subset of tunable connectors can be an empty subset. In such implementations, current may not be permitted to flow across any of the tunable connectors of a set of tunable connectors.

Each qubit of the one or more superconducting qubits is delineated by a closed superconductive path. For a single loop qubit, each closed superconductive path can include one superconducting qubit loop. For a multi-loop qubit, each closed superconductive path can include at least two superconducting qubit loops that are part of a same contiguous, unbroken electrical path.

For each configured single loop qubit, a respective closed superconductive path includes one superconductive arm of the set of superconductive arms, and at least a portion of a corresponding Josephson junction of the set of Josephson junctions. In some implementations, a single loop qubit can be formed when a Josephson junction of the set of Josephson junctions is electrically arranged between first and second connection nodes of a superconductive arm, and the first and second connection nodes are only directly coupled to superconductive arm connection lines interrupted by tunable connectors that do not permit current to flow therethrough (i.e., all set to “OFF” states).

For each configured multi-loop qubit, a respective closed superconductive path can include: at least two superconductive arms; at least a portion of at least one Josephson junction of the set of Josephson junctions that is electrically arranged between first and second connection node of a respective one of the at least two superconductive arms; at least two superconductive arm connection lines electrically arranged to connect first and second connection nodes of each of the at least two superconductive arms to one of a first connection node or a second connection node of each other one of the at least two superconductive arms; and, at least two tunable connectors of the first subset of tunable connectors that each interrupt a respective one of the at least two superconductive arm connection lines.

In some implementations, the superconducting circuit can be configured to provide both single-loop and multi-loop superconducting qubits.

For instance, in an implementation where superconducting circuit 400 is programmed to produce superconducting circuit configuration 600a of FIG. 6A, multi-loop horizontal qubit 610, first single-loop qubit 614, and second single-loop qubit 616 are provided. A respective closed superconductive path is configured to delineate each of the three superconducting qubits. The closed superconductive path for first single-loop qubit 614 includes first superconductive arm 402a and at least a portion of first flux qubit CJJ 404a. The closed superconductive path for second single-loop qubit 616 includes third superconductive arm 402c and at least a portion of third flux qubit CJJ 404c.

The closed superconductive path for horizontal qubit 610 includes: first horizontal qubit loop 610a, second horizontal qubit loop 610b, and third horizontal qubit loop 610c, which collectively comprise: second and fourth superconductive arms 402b, 402d; second and fourth flux qubit CJJs 404b, 404d; and, a first subset of superconductive arm connection lines 412 that are Interrupted by a first subset of tunable connectors consisting of: first, fourth, sixth, and seventh connecting CJJs 406a, 406d, 406f, and 406g.

Configuring the closed superconductive paths includes selectively electrically coupling superconductive arms of the set of superconductive arms based on the arrangement of superconductive arm connection lines interrupted by tunable connectors that permit current transmission.

In implementations where the first subset of tunable connectors is an empty subset, current does not travel through any of the tunable connectors and their respective superconductive arm connection lines, such that it is selectively configured that none of the superconductive arms are electrically coupled to one another. As a result, each closed superconductive path is limited to Josephson junctions of the set of Josephson junctions and their correspondingly connected superconductive arms. Each qubit is a single-loop qubit.

In implementations where the first subset of tunable connectors includes a plurality of tunable connectors, at least one closed superconductive path of at least one multi-loop qubit can be configured. As current can be transmitted across the first subset of tunable connectors, two or more superconductive arms are selectively electrically coupled based on an arrangement of superconductive arm connection lines extending therebetween that are interrupted by tunable connectors of the first subset of tunable connectors.

For example, for applying method 1000 to program superconducting circuit 400 (FIG. 4) to have superconducting circuit configuration 500a (FIG. 5A), first qubit 510 and is configured by the electrical coupling of first and second superconductive arms 402a, 402b. Second and fourth connecting CJJs 406b, 406d are part of the first subset of tunable connectors, and their “ON” states enables current to flow between first and second superconductive arms 402a, 402b. This establishes second superconducting first qubit loop 510b delimited by: at least a portion of each of first and second flux qubit CJJs 404a, 404b, and superconductive arm connection lines 412 interrupted by second and fourth connecting CJJs 406b, 406d of a first subset of tunable connectors. Second superconducting first qubit loop 510b is part of a closed superconductive path of first qubit 510 comprising first, second, and third superconducting first qubit loops 510a, 510b, 510c, in which first and third superconducting first qubit loops 510a, 510c respectively include first and second superconductive arms 402a, 402b.

Following act 1004, method 1000 is complete and an architecture of one or more superconducting qubits is configured or otherwise established on the superconducting circuit. At this point, a topological representation of a problem can be mapped onto a quantum processor that includes the superconducting circuit for solving the problem using quantum computation. Method 1000 can be invoked again by a call from a user or as part of another program to selectively reconfigure the qubit architecture of the superconducting circuit. Selective reconfiguration beneficially provides a flexible quantum processor topology that can be modified to best suit each particular problem. Therefore, a single quantum processor comprising one or more of the described superconducting circuit can be used to map several problems with different levels of complexity and/or variable connectivity without limiting efficiency. This can reduce a number of quantum processors with differing topologies needed to effectively serve one's needs.

For example, before a first invocation of method 1000, superconducting circuit 400 can have four uncoupled single-loop qubits 408 arranged thereon. The first invocation of method 1000 can selectively reconfigure the architecture of superconducting circuit 400 to include first and second qubits 510, 520 of superconducting circuit configuration 500a (FIG. 5A). Afterwards, a second invocation of method 1000 can selectively reconfigure the architecture of superconducting circuit 400 to no longer have the qubit arrangement of superconducting circuit configuration 500a, but instead have the arrangement of superconducting circuit configuration 600a (FIG. 6A) that includes horizontal qubit 610 and first and second single-loop qubits 614, 616.

In at least some implementations, method 1000 can, for example, include receiving a qubit configuration specification. The qubit configuration specification can specify a desired or target architecture, arrangement or topology of superconducting circuit 400 that can be realized configuration. A classical or digital computer can, for example, instructing an analog computer to configure the superconducting circuit according to the received qubit configuration specification through transmission of a plurality of control signals as generally described in the present disclosure.

A person skilled in the art would recognize that method 1000 can invoked any number of times to reconfiguring qubits on any of the superconducting circuits described herein. Method 1000 can be used to reconfigure any of the superconducting circuits described herein to and from any of the superconducting circuit configurations described herein, or other possible superconducting circuit configurations.

In some implementations, coupling compensation can be performed between two qubits that have been configured on a superconducting circuit by method 1000.

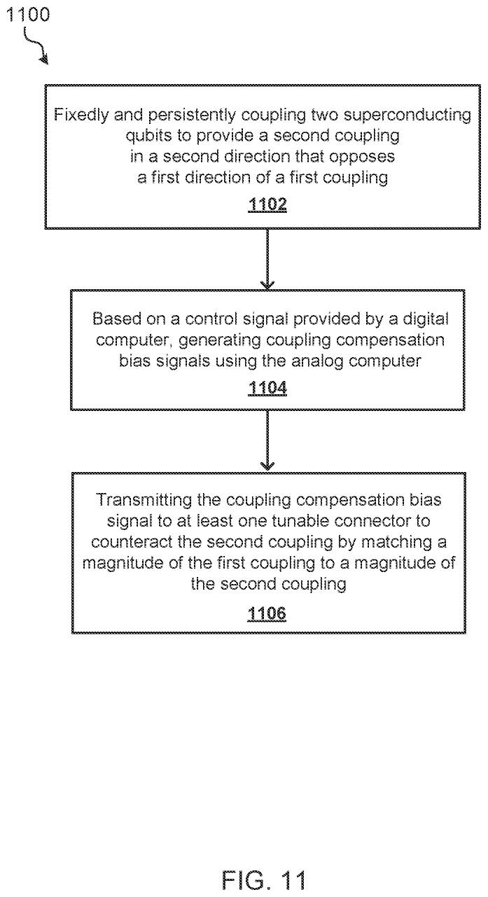

FIG. 11 is a method 1100 to configure a coupling between two qubits provided by a programmable superconducting circuit, in accordance with the present systems, devices, and methods.

In some implementations, method 1100 is performed by at least one digital processor in communication with at least one analog processor. To perform method 1100, the digital processor of may provide control signals or instructions to the analog processor to perform programming thereof.

In at least some implementations, method 1100 can be executed on computing system 100 including digital computer 102 having digital processor 106 in communication with at least one of quantum computer 104, quantum processor 126, or the quantum processor consisting of circuit 200.

Method 1100 comprises acts 1102, 1104, and 1106; however, a person skilled in the art will understand that the number of acts illustrated is an example, and, in some implementations, certain acts may be omitted, further acts may be added, and/or the order of the acts may be changed.

Prior to executing method 1100, a superconducting circuit, such as one of superconducting circuits 400 (FIGS. 4), 700a (FIG. 7A), and 800a (FIG. 8A), can be programmed to have at least two qubits, such as in one of superconducting circuit configurations 500a, 500b, 700b, 700c, and 800a that each include two multi-loop qubits or superconducting circuit configurations 600a and 600b that each include one multi-loop qubit and two single-loop qubits. A first subset of tunable connectors can be configured to electrically couple superconductive arms across superconductive arm connection lines 412, 712, 812 that are interrupted by the first subset of tunable connectors, enabling transmission of current therebetween (i.e., set to an “ON” state). A second subset of tunable connectors can be configured to inhibit current transmission between superconductive arms (i.e., set to an “OFF” state). However, one or more tunable connectors of the second subset of tunable connectors might not inhibit all flow of current. As such, in some implementations there may be a small, undesired residual coupling between two configured qubits. This residual coupling is a first coupling having a first direction and a first magnitude. Coupling compensation can be performed using method 1100 to eliminate at least a majority of the residual coupling between the two qubits.

For instance, superconducting circuit 400 may be programmed in superconducting circuit configuration 500a having first qubit 510 and second qubit 520. Though in the “OFF” state, a small amount of current can pass through one or more CJJ of a second subset of connecting CJJs that includes: first, third, sixth, and eighth connecting CJJs 406a, 406c, 406f, 406h, such that first and second qubits 510, 520 are undesirably electrically coupled by a first coupling in a first direction.

At 1102, first and second superconducting qubits are fixedly and persistently magnetically coupled. The fixed, persistent magnetic coupling is a second coupling having a second direction that substantially opposes the first direction of the first coupling. The second coupling is provided by a coupling superconducting loop and has a fixed magnitude that it cannot be tuned. In some implementations, the coupling superconducting loop is a permanent magnetic, though this is not intended to be limiting. In some implementations, a magnitude of the second coupling exceeds a magnitude of the undesired residual coupling of the first coupling.

For instance, in implementations where superconducting circuit 400 (FIG. 4) is programmed to have superconducting circuit configuration 500a (FIG. 5A), connecting CJJs 406a, 406c, 406f, 406h in the “OFF” state can initially provide unwanted residual coupling in a first direction (i.e., a first coupling) between first and second qubits 510, 520. Performing coupling compensation can result in the arrangement of superconducting circuit configuration 900a. Coupling superconducting loop 902 can be used to provide fixed, persistent magnetic coupling between first qubit 510 and second qubit 520 (i.e., a second coupling). The direction of the fixed, persistent magnetic coupling between first and second qubits 510, 520 provided by coupling superconducting loop 902 can be in a direction substantially opposing the first direction of the residual coupling.

In some implementations, fixedly and persistently magnetically coupling the first and second qubits via a coupling superconducting loop can include forming the coupling superconducting loop comprising a material that exhibits superconducting properties at and below a critical temperature. Examples of such materials include but are not limited to: aluminum, niobium, and tantalum. In some implementations, forming the coupling superconducting loop can include one or more of depositing, etching, and/or planarizing the superconducting material.

In some implementations, the fixed, persistent magnetic coupling can include forming more than one coupling superconducting loop.

At 1104, coupling compensation bias signals are generated using the analog computer based on a control signal provided by a digital computer.

A coupling compensation control signal can be transmitted to a DAC of the analog computer. The DAC of the analog computer can be at least one of the one or more DACs used to configure qubits on the superconducting circuit, such as those used to configure which tunable connectors permit current transmission thereacross in the execution of method 1000.

In some implementations, digital processor 106 (FIG. 1) can execute instructions for coupling compensation stored in system memory 122 for interfacing with quantum computer 104, including the configured superconducting circuit. The execution of such instruction can cause digital processor 106 to transmit coupling compensation control signals via controller 118 to coupler control system 132 of quantum computer 104. In some implementations, the one or more DACs that are used to program the qubit architecture can be part of coupler control system 132. In some implementations, all coupling compensation control signals can be transmitted to a same DAC or to more than one of the DACs of the analog computer.

In some implementations, one or more coupling compensation bias signals are generated using the DAC of the analog controller. In some implementations, each of the one or more coupling compensation bias signals is a flux bias signal.

At 1106, the coupling compensation bias signal is transmitted to at least one tunable connector of the second subset of tunable connectors in order to counteract the second coupling. Tuning at least one tunable connector of the second subset changes the first coupling, which previously was provided by only the undesired residual coupling. The application of the coupling compensation bias signal modifies the magnitude of the first coupling to match a magnitude of the second coupling. As the first direction of the first coupling is substantially opposite to the second direction of the second coupling, application of the coupling compensation bias signal can result in a net zero coupling between the first and second superconducting qubits.

The coupling compensation bias signal can be transmitted from one or more DACs of the analog computer to at least one of the tunable connectors of the second subset of tunable connectors. In one implementation, each coupling compensation bias signal can be applied to a respective tunable connector of the subset of tunable connectors via a respective inductive interface, such as connecting CJJ interface 414, or via an analog line.

After 1106, method 1100 is complete, and quantum computation can be executed using the superconducting quantum processor including at least one coupling-compensated, configured superconducting circuit.

Using method 1100, coupling compensation is achieved by providing fixed, persistent magnetic coupling between two configured qubits to counteract undesired residual coupling in a first direction provided by tunable connectors. A resultant coupling in a second direction caused by the fixed, persistent magnetic coupling can subsequently be adjusted for by tuning the tunable connectors to produce an equal and opposite coupling. Though need for coupling compensation may partially stem from imperfect operation of one or more tunable connectors, the selectively configurable nature of the tunable connectors can be leveraged to remedy undesired coupling. Outside of the loop for fixedly and persistently magnetically coupling two qubits, no additional circuitry must be introduced to perform the described coupling compensation since the tunable connector and the DAC used to program the tunable connector are already part of the superconducting circuit and/or the analog processor to which it belongs.

### Post-Amble

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the example methods for quantum computation generally described above.

The various implementations described above can be combined to provide further implementations. All of the commonly assigned U.S. patent application publications, U.S. patent applications, foreign patents, and foreign patent applications referred to in this specification and/or listed in the Application Data Sheet are incorporated herein by reference, in their entirety, including but not limited to: U.S. Pat. Nos. 7,533,068; 7,984,012; 8,008,942; 8,190,548; 8,195,596; 8,244,662; 8,421,053; 8,536,566; 8,772,759; 8,854,074; 9,170,278;

9,178,154; 9,424,526; 9,501,747; and, 11,507,871 (published as U.S. Patent Application Publication No. 2019/0220771); U.S. Provisional Patent Application No. 63/227,395; International Patent Application PCT/US 2021/031373 (published as International Patent Application Publication No: WO2021/231224); International Patent Application PCT/US2022/038498 (published as International Patent Application Publication No. WO2023/009609); and, PCT/US2022/081515 (published as International Patent Application Publication No. WO2023/219656). These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A superconducting circuit having a configurable architecture of one or more superconducting qubits, the superconducting circuit comprising:
a set of superconductive arms, each of the superconductive arms of the set of superconductive arms respectively comprised of a first connection node, a second connection node, and a trace of superconductive material having an open shape that extends from the first connection node to the second connection node;
a set of Josephson junctions, wherein each Josephson junction of the set of Josephson junctions is electrically arranged between the first and the second connection nodes of a respective one of the superconductive arms to selectively close the open shape; and,
a configuration circuit, the configuration circuit comprising:
a set of superconductive arm connection lines, wherein each first connection node of each superconductive arm is physically and electrically connected to at least one of the first or the second connection node of at least one other superconductive arm via one or more superconductive arm connection lines extending therebetween, and each second connection node of each superconductive arm is physically and electrically connected to at least one of the first or the second connection node of at least one other superconductive arm via one or more superconductive arm connection lines extending therebetween, and
a set of tunable connectors, each tunable connector of the set of tunable connectors interrupting a respective superconductive arm connection line of the set of superconductive arm connection lines, and the tunable connectors selectively operable to control a flow of current therethrough and across two or more superconductive arm connection lines between at least two superconductive arms and configure closed superconductive paths that form the one or more superconducting qubits.

2. The superconducting circuit of claim 1, wherein each Josephson junction of the set of Josephson junctions is operable to tune a double-well potential of a superconducting qubit of the one or more superconducting qubits, wherein each superconducting qubit includes: one Josephson junction of the set of Josephson junctions or two Josephson junctions of the set of Josephson junctions.

3. The superconducting circuit of claim 1, wherein each Josephson junction of the set of Josephson junctions is one of: a compound Josephson junction (CJJ) or a compound-compound Josephson junction (CCJJ).

4. The superconducting circuit of claim 1, wherein the superconducting circuit is configurable such that the one or more superconducting qubits selectively includes at least one qubit with a respective closed superconductive path formed of more than one superconducting qubit loops, each comprising:
at least two superconductive arms of the set of superconductive arms;
at least two superconductive arm connection lines interrupted by tunable connectors of the set of tunable connectors tuned to enable current flow between the at least two superconductive arms, each of the at least two superconductive arm connection lines electrically arranged to connect first and second connection nodes of each of the at least two superconductive arms to one of a first connection node or a second connection node of each other one of the at least two superconductive arms; and
one or more Josephson junctions of the set of Josephson junctions, each Josephson junction of the one or more Josephson junctions being electrically arranged between respective first and second connection nodes of a respective one of the at least two superconductive arms.

5. The superconducting circuit of claim 4, wherein one or more tunable connectors of the set of tunable connectors tuned to enable current flow between the at least two superconductive arms are operable as one or more L-tuners to tune a qubit inductance of the at least one qubit having more than one superconducting qubit loop.

6. The superconducting circuit of claim 1, wherein superconducting circuit is configurable such that the one or more superconducting qubits includes at least one qubit with a respective closed superconductive path formed of one superconducting qubit loop, each comprising: one superconductive arm of the set of superconductive arms and at least a portion of a Josephson junction of the set of Josephson junction that is electrically arranged between the first and the second connection nodes of the one superconductive arm.

7. The superconducting circuit of claim 1, wherein each tunable connecting element of the set of tunable connectors is selectively switchable between: an “ON” state and an “OFF” state, wherein:
each tunable connectors in the “OFF” state substantially prevents current transmission across a respective superconductive arm connection line, and
each tunable connector of the set of tunable connectors in the “ON” state enables current transmission across a respective superconductive arm connection line between two superconductive arms of the set of superconductive arms, forming a portion of a closed superconductive path of one of the one or more superconducting qubits.

8. The superconducting circuit of claim 7, wherein the one or more superconducting qubits comprise: one or more single-loop qubits, each single-loop qubit comprising: a respective superconductive arm of the set of superconductive arms and at least a portion of a respective Josephson junction of the set of Josephson junctions electrically arranged between a respective first and second connection node of the respective superconductive arm, and wherein each of the superconductive arm connection lines directly coupled to the first and the second connection nodes of the respective superconductive arm are interrupted by tunable connectors of the set of tunable connectors configured to the “OFF” state.

9. The superconducting circuit of claim 7 configured to include a first superconducting qubit and a second superconducting qubit, and wherein at least one tunable connector of the set of tunable connectors set to the “OFF” state provides an undesired first coupling between the first and the second qubit in a first direction, the superconducting circuit further comprises at least one coupling superconducting loop to fixedly and persistently magnetically couple the first superconducting qubit and the second superconducting qubit with a second coupling in a second direction that opposes the first direction, wherein the second coupling counteracts the first coupling.

10. The superconducting circuit of claim 9, wherein the at least one tunable connector of the set of tunable connectors in the “OFF” state is tunable to modify a magnitude of the first coupling to match a magnitude of the second coupling.

11. The superconducting circuit of claim 1, wherein each trace of superconducting material of the set of superconductive arms, the set of Josephson junctions, and the set of tunable connectors each comprise of one or more materials that exhibit superconducting behavior at and below a respective critical temperature of each of the one or more materials.

12. The superconducting circuit of claim 1, wherein each tunable connector of the set of tunable connectors is selectively configurable to transmit current therethrough via modification of a respective tunable connector inductance, each respective tunable connector inductance being modifiable through a bias signal transmitted to each tunable connector via a respective bias interface.

13. The superconducting circuit of claim 1, wherein a maximum number of the one or more superconducting qubits corresponds to a number of Josephson junctions in the set of Josephson junctions.

14. The superconducting circuit of claim 1, wherein the configurable architecture of one or more superconducting qubits includes one of: at least one qubit with a respective closed superconductive path having more than one superconducting qubit loop; at least one qubit with a respective closed superconductive path having one superconducting qubit loop; or, a combination thereof.

15. The superconducting circuit of claim 1, wherein the configurable architecture of one or more superconducting qubits of the superconducting circuit is reconfigurable to provide a different architecture of one or more superconducting qubits based on selective reconfiguration of the set of tunable connectors to electrically couple superconductive arms of the set of superconductive arms.

16. The superconducting circuit of claim 1, wherein a respective trace of at least one of the superconductive arms of the set of superconductive arms is U shaped.

17. A method to configure one or more superconducting qubits on a superconducting circuit including: a set of superconductive arms, each comprised of a trace of superconductive material having an open shape that extends between a respective first and second connection node; a set of Josephson junctions, each electrically arranged between the first and the second connection node of a respective one of the superconductive arms; a set of superconductive arm connection lines extending between one of the first and the second connection node of a superconductive arm of the set of superconductive arms and one of the first and the second connection node of another superconductive arm of the set of superconductive arms; and, a set of tunable connectors, each interrupting a respective superconductive arm connection line, the method comprising:
transmitting a plurality of bias signals to the superconducting circuit, each bias signal of the plurality of bias signals transmitted to a respective tunable connector of the set of tunable connectors; and
based on the plurality of bias signals, configuring a first subset of tunable connectors of the set of tunable connectors to permit current transmission therethrough, wherein an arrangement of superconductive arm connection lines that are interrupted by the first subset of tunable connectors selectively electrically couples superconductive arms of the set of superconductive arms to configure a closed superconductive path of each qubit of the one or more superconducting qubits, each closed superconductive path comprising at least: at least one superconductive arm of the set of superconductive arms and at least a portion of at least one Josephson junction of the set of Josephson junctions.

18. The method of claim 17, wherein prior to the transmitting the plurality of bias signals to the superconducting circuit, the method comprises:
inputting a desired qubit configuration to a digital computer; and
using the digital computer, instructing an analog computer that includes the superconducting circuit to perform configuration of the one or more superconducting qubits by transmitting one or more control signals.

19. The method of claim 18 comprising:
receiving, by one or more digital-to-analog converters (DACs) of the analog computer, the one or more control signals transmitted by the digital computer;
generating, by the one or more DACs, the plurality of bias signals; and
the transmitting the plurality of bias signals to the superconducting circuit includes applying each bias signal to the respective tunable connector via a respective bias interface.

20. The method of claim 19, wherein the applying each bias signal to a respective tunable connector via a respective bias interface comprises one of:
applying each bias signal to a respective tunable connector via an analog line, or
coupling each bias signal to a respective tunable connector via an inductive interface.

21. The method of claim 17, wherein the configuring the first subset of tunable connectors of the tunable connectors to permit current transmission through the first subset of tunable connectors comprises:
applying a first subset of the plurality of bias signals to configure the first subset of tunable connectors to an “ON” state; and
applying a second subset of the plurality of bias signals to configure a second subset of tunable connectors to an “OFF” state, wherein the second subset of tunable connectors configured to the “OFF” state inhibit current transmission through the second subset of tunable connectors.

22. The method of claim 17 further comprising selectively tuning one or more tunable connectors of the first subset of tunable connectors to compensate for qubit inductance of a superconducting qubit formed by a respective closed superconductive path that includes a superconductive arm connection line interrupted by the one or more tunable connectors.

23. The method of claim 22, wherein the superconducting circuit is included as part of an analog computer that is communicatively coupled to a digital computer, and the selectively tuning the one or more tunable connectors of the first subset of tunable connectors comprises:
receiving, by one or more digital-to-analog converters (DACs) of the analog computer, one or more inductance tuning control signals transmitted by the digital computer;
generating, by the one or more DACs, one or more inductance tuning bias signals; and
transmitting each of the one or more inductance tuning bias signals to a respective one of the one or more tunable connectors of the first subset of tunable connectors.

24. The method of claim 17, further comprising performing coupling compensation between a first and a second superconducting qubit configured on the superconducting circuit having a first coupling therebetween, the first coupling having a first direction, wherein the performing coupling compensation includes:
fixedly and persistently magnetically coupling the first superconducting qubit to the second superconducting qubit by a second coupling having a second direction that substantially opposes the first direction; and
tuning the first coupling through at least one tunable connector of a second subset of tunable connectors of the set of tunable connectors to counteract the second coupling, including matching a magnitude of the first coupling to a magnitude of the second coupling.

25. The method of claim 24, wherein the superconducting circuit is included as part of an analog computer that is communicatively coupled to a digital computer, the tuning the first coupling through at least one tunable connector of the second subset of tunable connectors to counteract the second coupling comprises:
receiving, by one or more digital-to-analog converters (DACs) of the analog computer, a coupling compensation control signal transmitted by the digital computer;
generating, by the one or more DACs, one or more coupling compensation bias signals; and
transmitting each of the one or more coupling compensation signals to a respective one of the at least one tunable connectors of the second subset of tunable connectors via a respective tunable connector interface.

26. The method of claim 24, wherein the fixedly and persistently magnetically coupling the first and second superconducting qubits comprises providing at least one coupling superconducting loop, each coupling superconducting loop to magnetically couple a superconducting loop of the first superconducting qubit to a superconducting loop of the second superconducting qubit.

27. A method to configure one or more superconducting qubits on a superconducting circuit, the method performed by a digital processor in communication with an analog computer that comprises the superconducting circuit, the superconducting circuit including: a set of superconductive arms, each comprised of a trace of superconductive material having an open shape that extends between a respective first and second connection node; a set of Josephson junctions, each electrically arranged between the first and the second connection node of a respective one of the superconductive arms; a set of superconductive arm connection lines extending between one of the first and the second connection node of a superconductive arm of the set of superconductive arms and one of the first and the second connection node of another superconductive arm of the set of superconductive arms; and, a set of tunable connectors, each interrupting a respective superconductive arm connection line, the method comprising:
receiving a qubit configuration specification; and
instructing the analog computer to configure the superconducting circuit according to the received qubit configuration specification through transmission of a plurality of control signals, the plurality of control signals to tune a first subset of tunable connectors to permit current transmission therethrough to selectively electrically couple superconductive arms of the set of superconductive arms and establish a closed superconductive path of each qubit of the one or more superconducting qubits, each closed superconductive path comprising at least: at least one superconductive arm of the set of superconductive arms and at least a portion of at least one Josephson junction of the set of Josephson junctions.

28. The method of claim 27, wherein the instructing the analog computer to configure the superconducting circuit according to the received qubit configuration specification through transmission of a plurality of control signals comprises: transmitting the plurality of control signals to one or more digital-to-analog converters (DACs) of the analog computer to generate a plurality of bias signals for application to the set of tunable connectors via bias interfaces, the application of the plurality of bias signals to tune the first subset of tunable connectors to permit current transmission therethrough.

29. The method of claim 27, wherein the instructing the analog computer to configure the superconducting circuit according to the received qubit configuration specification through transmission of a plurality of control signals comprises:
transmitting a first subset of control signals of the plurality of control signals to configure the first subset of tunable connectors to an “ON” state; and
transmitting a second subset of the plurality of control signals to configure a second subset of tunable connectors to an “OFF” state, wherein the second subset of tunable connectors configured to the “OFF” state inhibit current transmission through the second subset of tunable connectors.

30. The method of claim 27, further comprising: instructing the analog computer to selectively tune one or more tunable connectors of the first subset of tunable connectors to compensate for qubit inductance of a superconducting qubit formed by a respective closed superconductive path that includes a superconductive arm connection line interrupted by the one or more tunable connectors.

31. The method of claim 30, wherein the instructing the analog computer to selectively tune one or more tunable connectors of the first subset of tunable connectors to compensate for qubit inductance comprises: transmitting one or more inductance tuning control signals to one or more digital-to-analog converters (DACs) of the analog computer to generate one or more inductance tuning bias signals for application to the one or more tunable connectors of the first subset of tunable connectors to tune inductance values.

32. The method of claim 27, further comprising instructing the analog computer to perform coupling compensation between a first and a second superconducting qubit configured on the superconducting circuit, the first and the second superconducting qubit having an undesired first coupling therebetween having a first direction and a second coupling having a second direction that substantially opposes the first direction, the second coupling being a fixed, persistent magnetic coupling,
wherein the instructing the analog computer to perform coupling compensation between a first and a second superconducting qubit comprises: instructing the analog computer to tune the undesired first coupling through at least one tunable connector of a second subset of tunable connectors of the set of tunable connectors to counteract the second coupling, including matching a magnitude of the first coupling to a magnitude of the second coupling.

33. The method of claim 32, the instructing the analog computer to tune the undesired first coupling through at least one tunable connector of a second subset of tunable connectors of the set of tunable connectors to counteract the second coupling comprising: transmitting a coupling compensation control signal to one or more digital-to-analog converters (DACs) of the analog computer to generate one or more coupling compensation bias signals for application to the at least one tunable connector of the second subset of tunable connectors.
